(19) United States
(12) Patent Application Publication
(10) Pub. No.: US 2021/0022265 A1
(43) Pub. Date: Jan. 21, 2021

(54) COOLING DEVICE AND COOLING SYSTEM USING COOLING DEVICE

(71) Applicant: Furukawa Electric Co., Ltd., Tokyo (JP)

(72) Inventors: Yoshikatsu INAGAKI, Tokyo (JP); Hirofumi AOKI, Tokyo (JP); Hiroshi OKADA, Tokyo (JP); Kenya KAWABATA, Tokyo (JP); Tomoaki TORATANI, Tokyo (JP)

(73) Assignee: Furukawa Electric Co., Ltd., Tokyo (JP)

(21) Appl. No.: 17/061,468

(22) Filed: Oct. 1, 2020

Related U.S. Application Data
(63) Continuation of application No. PCT/JP2019/035632, filed on Sep. 11, 2019.

(30) Foreign Application Priority Data
Sep. 14, 2018 (JP) 2018-173037
Oct. 11, 2018 (JP) 2018-192929
Nov. 30, 2018 (JP) 2018-226033

(51) Int. Cl. H05K 7/20

(52) U.S. Cl. CPC H05K 7/20318; H05K 7/20336

(57) ABSTRACT

The present disclosure provides a cooling device that can exhibit excellent cooling characteristics while avoiding increase in size of the device, and a cooling system using the cooling device. The cooling device including a container to which at least one heating element is thermally connected, a primary refrigerant sealed in an inside of the container, and a condensation tube through which a secondary refrigerant flows, and which penetrates through a gaseous phase portion inside of the container.

### CROSS REFERENCE TO RELATED APPLICATIONS

The present application is a continuation application of International Patent Application No. PCT/JP2019/035632 filed on Sep. 11, 2019, which claims the benefit of Japanese Patent Application No. 2018-173037, filed on Sep. 14, 2018 and Japanese Patent Application No. 2018-192929, filed on Oct. 11, 2018 and Japanese Patent Application No. 2018-226033, filed on Nov. 30, 2018. The contents of these applications are incorporated herein by reference in their entirety.

### BACKGROUND

### Technical Field

The present disclosure relates to a cooling device that cools electric/electronic components and the like, and particularly relates to a cooling device that can cool electric/electronic components and the like having a large heat generation amount to a predetermined allowable temperature without increasing a size of the cooling device.

### Background

With the advancement of functions of electronic devices, heating elements such as electric/electronic components are mounted at high density inside the electronic devices, and the heat generation amount of the heating elements is increasing. If the temperature of the heating element such as electric/electronic components rises above the predetermined allowable temperature, it becomes the cause of malfunctioning of the electric/electronic components and the like, and therefore it is important to keep the temperature of the heating elements such as electric/electronic components at the allowable temperature or less. Therefore, a cooling device for cooling electric/electronic components and the like is mounted inside the electronic device.

On the other hand, since the heating elements such as electric/electronic components are mounted at a high density as described above, the space in which the cooling device can be installed is limited. Therefore, the cooling device is required to further improve the cooling characteristics while avoiding an increase in size.

Therefore, in order to stably cool even electric/electronic components and the like in which the amount of heat generation is increased, there has been proposed a loop heat pipe using an evaporator including a case having a porous body having a plurality of tubular protruded portions, a liquid chamber that serves as both a steam chamber and a liquid reservoir tank separated by the porous body, a first portion to which a steam pipe is connected, and which defines the steam chamber, a second portion with a liquid pipe connected to one side, having a lower thermal conductivity than the first portion, and defining the liquid chamber, and a plurality of projected portions that are provided in the first portion, project toward a side of the second portion, and are fitted respectively to the plurality of tubular protruded portions of the porous body (Japanese Patent Application Laid-open No. 2014-214985). In Japanese Patent Application Laid-open No. 2014-214985, cooling performance is improved by smoothing a phase change from a liquid phase to a gaseous phase of a working fluid by the porous body having the plurality of tubular protruded portions.

However, in Japanese Patent Application Laid-open No. 2014-214985 that is a loop heat pipe, the working fluid that receives heat from the heating element in the evaporator and changes in phase from the liquid phase to the gaseous phase is carried out to a heat radiation fin unit that is heat exchanging means from the evaporator, has heat exchanged in the heat radiation fin unit to radiate heat to the heat radiation fin unit, and changes in phase from the gaseous phase to the liquid phase. Heat exchange function of the heat radiation fin unit is by cooling air supplied to the heat radiation fin unit, and therefore, in order to improve the heat exchange function of the heat radiation fin unit, it is necessary to increase the fin area, in other words, to increase the size of the device. Accordingly, in the loop heat pipe as in Japanese Patent Application Laid-open No. 2014-214985, there is room for improvement in improving the cooling characteristics while avoiding an increase in size.

Further, in the loop heat pipe as in Japanese Patent Application Laid-open No. 2014-214985, the working fluid in a gaseous phase in the evaporator is carried out from the evaporator and has heat exchanged, and thereby changes in phase to the liquid phase, and the working fluid in a liquid phase flows back into the evaporator from the heat radiation fin unit. Accordingly, in the loop heat pipe as in Japanese Patent Application Laid-open No. 2014-214985, there is room for improvement in the cooling characteristics also in that control of flow of the working fluid is not easy.

### SUMMARY

In the light of the above described circumstances, an object of the present disclosure is to provide a cooling device that can exhibit excellent cooling characteristics while avoiding increase in size of the device and a cooling system using the cooling device.

A gist of a configuration of a cooling device and a cooling system using the cooling device of the present disclosure is as follows.

[1] A cooling device including a container to which at least one heating element is thermally connected, a primary refrigerant sealed in an inside of the container, and a condensation tube through which a secondary refrigerant flows, and which penetrates through a gaseous phase portion in the inside of the container.

[2] The cooling device described in [1], wherein the heating element is thermally connected to a part where the primary refrigerant in a liquid phase exists or a vicinity of the part where the primary refrigerant in a liquid phase exists, on an outer surface of the container.

[3] The cooling device described in [1] or [2], wherein a container inner surface area increasing portion that increases a contact area with the primary refrigerant in a liquid phase is formed on an inner surface of the container to which the heating element is thermally connected.

[4] The cooling device described in [3], wherein the container inner surface area increasing portion is immersed in the primary refrigerant in a liquid phase.

[5] The cooling device described in [3] or [4], wherein the container inner surface area increasing portion is a plate-shaped fin, a pin fin and/or a dent.

[6] The cooling device described in any one of [3] to [5], wherein the container inner surface area increasing portion includes a thermal conductive member.

[7] The cooling device described in [6], wherein the thermal conductive member is a metal member or a carbon member.

[8] The cooling device described in any one of [3] to [7], wherein at least a part of the container inner surface area increasing portion is a sintered body of a thermal conductive material or an aggregate of a particulate thermal conductive material.

[9] The cooling device described in [8], wherein the sintered body of the thermal conductive material is a metal sintered body, and the metal sintered body is a sintered body of at least one kind of metal material selected from a group including metal powder, metal fiber, metal mesh, metal braid and metal foil.

[10] The cooling device described in [8], wherein the aggregate of the particulate thermal conductive material is an aggregate of carbon particles.

[11] The cooling device described in any one of [1] to [10], wherein a condensation tube outer surface area increasing portion that increases a contact area with the primary refrigerant in a gaseous phase is formed on an outer surface of the condensation tube.

[12] The cooling device described in any one of [1] to [11], wherein a condensation tube inner surface area increasing portion that increases a contact area with the secondary refrigerant is formed on an inner surface of the condensation tube.

[13] The cooling device described in any one of [1] to [12], wherein a plurality of the condensation tubes are disposed in parallel.

[14] The cooling device described in any one of [1] to [13], wherein a plurality of the condensation tubes are disposed in layers.

[15] The cooling device described in any one of [1] to [14], wherein the condensation tube is located above the container inner surface in a part to which a heating element is thermally connected, in a direction of gravity.

[16] The cooling device described in any one of [1] to [15], wherein the condensation tube includes a part overlapping the heating element in plan view.

[17] The cooling device described in any one of [1] to [16], wherein in the condensation tube, the secondary refrigerant having a lower temperature than an allowable maximum temperature of the heating element flows.

[18] The cooling device described in any one of [1] to [17], wherein a shape in an orthogonal direction to a longitudinal direction in at least a partial region, of the condensation tube in the inside of the container, differs from a shape in an orthogonal direction to a longitudinal direction, of the condensation tube in an outside of the container.

[19] The cooling device described in any one of [1] to herein a secondary refrigerant storing block in which the secondary refrigerant is stored is further provided in the condensation tube, and the secondary refrigerant storing block is thermally connected to the container.

[20] The cooling device described in any one of [1] to [19], wherein a heat radiation fin is further provided on an outer surface of the container.

[21] A cooling system in which a cooling device including a container to which at least one heating element is thermally connected, a primary refrigerant sealed in an inside of the container, and a condensation tube through which a secondary refrigerant flows, and which penetrates through a gaseous phase portion in the inside of the container, and a secondary refrigerant cooling portion to which the condensation tube extending from the cooling device is connected are used, and the condensation tube circulates in the cooling device and the secondary refrigerant cooling portion, wherein

in the inside of the container thermally connected to the heating element, the primary refrigerant receiving heat from the heating element changes in phase to a gaseous phase from a liquid phase, the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, and the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

[22] A cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, wherein

the heat transport member includes a second container to which at least one heating element is thermally connected, an extended portion including an inner space communicating with an inside of the second container, and a tertiary refrigerant sealed in an inside of the heat transport member, and the extended portion contacts the primary refrigerant in a liquid phase.

[23] A cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, wherein

the heat transport member includes a second container to which at least one heating element is thermally connected, and a tertiary refrigerant sealed in an inside of the second container, and the second container contacts the primary refrigerant in a liquid phase.

[24] A cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, wherein

the heat transport member includes a base block to which at least one heating element is thermally connected, a heat pipe portion provided to stand on the base block, and a tertiary refrigerant sealed in an inside of the heat pipe portion, and the heat pipe portion contacts the primary refrigerant in a liquid phase.

[25] A cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, wherein

the heat transport member includes a base block to which at least one heating element is thermally connected, a heat pipe provided to be buried in the base block, and a tertiary refrigerant sealed in an inside of the heat pipe.

[26] The cooling device described in [22], wherein the second container contacts the primary refrigerant in a liquid phase.

[27] The cooling device described in [24] or [25], wherein the base block contacts the primary refrigerant in a liquid phase.

[28] The cooling device described in [22] or [23], wherein the heating element is thermally connected to a part where the tertiary refrigerant in a liquid phase exists or a vicinity of the part where the tertiary refrigerant in a liquid phase exists, on an outer surface of the second container.

[29] The cooling device described in [22] or [23], wherein a second container inner surface area increasing portion that increases a contact area with the tertiary refrigerant in a liquid phase is formed on an inner surface of the second container to which the heating element is thermally connected.

[30] The cooling device described in [22], wherein a heat transport member outer surface area increasing portion that increases a contact area with the primary refrigerant in a liquid phase is formed on an outer surface of the second container and/or the extended portion.

[31] The cooling device described in [23], wherein a heat transport member outer surface area increasing portion that increases a contact area with the primary refrigerant in a liquid phase is formed on an outer surface of the second container.

[32] The cooling device described in [24], wherein a heat transport member outer surface area increasing portion that increases a contact area with the primary refrigerant in a liquid phase is formed on an outer surface of the heat pipe portion.

[33] The cooling device described in any one of [30] to [32], wherein the heat transport member outer surface area increasing portion has recessed and protruded portions.

[34] The cooling device described in [33], wherein the recessed and protruded portions have a sintered body of a metal wire and/or a sintered body of metal powder.

[35] The cooling device described in [33], wherein the recessed and protruded portions have recessed and protruded portions formed by etching and/or polishing.

[36] The cooling device described in any one of [22] to [35], wherein a shape in an orthogonal direction to a longitudinal direction in at least a partial region, of the condensation tube in the inside of the first container differs from a shape in an orthogonal direction to a longitudinal direction, of the condensation tube in an outside of the first container.

[37] The cooling device described in any one of [22] to [36], wherein a secondary refrigerant storing block in which the secondary refrigerant is stored is further provided at the condensation tube, and the secondary refrigerant storing block is thermally connected to the first container.

[38] The cooling device described in any one of [22] to [37], wherein a heat radiation fin is further provided on the outer surface of the first container.

[39] A cooling system in which a cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a second container to which at least one heating element is thermally connected, an extended portion having an inner space communicating with an inside of the second container, and a tertiary refrigerant sealed in an inside of the heat transport member, the extended portion contacting the primary refrigerant in a liquid phase, and a secondary refrigerant cooling portion to which the condensation tube extending from the cooling device is connected are used, and the condensation tube circulates in the cooling device and the secondary refrigerant cooling portion, wherein

in the inside of the second container thermally connected to the heating element, the tertiary refrigerant receiving heat from the heating element changes in phase to a gaseous phase from a liquid phase, and the tertiary refrigerant in the gaseous phase flows in an inner direction of the extended portion from the inside of the second container and changes in phase to a liquid phase from the gaseous phase by a heat exchange action with the primary refrigerant, whereby heat is transferred to the primary refrigerant from the tertiary refrigerant, the primary refrigerant to which heat is transferred from the tertiary refrigerant changes in phase to a gaseous phase from the liquid phase in the inside of the first container, and the primary refrigerant of the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

[40] A cooling system in which a cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a second container to which at least one heating element is thermally connected, and a tertiary refrigerant sealed in an inside of the second container, with the second container contacting the primary refrigerant in a liquid phase, and a secondary refrigerant cooling portion to which the condensation tube extending from the cooling device is connected are used, and the condensation tube circulates in the cooling device and the secondary refrigerant cooling portion, wherein

in the inside of the second container thermally connected to the heating element, the tertiary refrigerant receiving heat from the heating element changes in phase to a gaseous phase from a liquid phase, and the tertiary refrigerant in the gaseous phase changes in phase to a liquid phase from the gaseous phase by a heat exchange action with the primary refrigerant via a wall surface of the second container, whereby heat is transferred to the primary refrigerant from the tertiary refrigerant, the primary refrigerant to which heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

[41] A cooling system in which a cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a base block to which at least one heating element is thermally connected, a heat pipe portion provided to stand on the base block, and a tertiary refrigerant sealed in an inside of the heat pipe portion, and the heat pipe portion contacts the primary refrigerant in a liquid phase, and a secondary refrigerant cooling portion to which the condensation tube extending from the cooling device is connected are used, and the condensation tube circulates in the cooling device and the secondary refrigerant cooling portion, wherein

heat is transferred to the heat pipe portion from the base block thermally connected to the heating element, the tertiary refrigerant sealed in the heat pipe portion receiving heat from the base block changes in phase to a gaseous phase from a liquid phase, and the tertiary refrigerant in the gaseous phase flows through an inside of the heat pipe portion and changes in phase to a liquid phase from the gaseous phase by a heat exchange action with the primary refrigerant, whereby heat is transferred to the primary refrigerant from the tertiary refrigerant, the primary refrigerant to which heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

[42] A cooling system in which a cooling device including a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a base block to which at least one heating element is thermally connected, a heat pipe provided to be buried in the base block, and a tertiary refrigerant sealed in an inside of the heat pipe, and a secondary refrigerant cooling portion to which the condensation tube extending from the cooling device is connected are used, and the condensation tube circulates in the cooling device and the secondary refrigerant cooling portion, wherein

heat is transferred to the heat pipe from the base block thermally connected to the heating element, the tertiary refrigerant sealed in the heat pipe receiving heat from the base block changes in phase to a gaseous phase from a liquid phase, the tertiary refrigerant in the gaseous phase flows through an inside of the heat pipe, heat is transferred to the primary refrigerant from the tertiary refrigerant, the primary refrigerant to which heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

In an aspect of the cooling device of the above described [1], the primary refrigerant sealed in the inside of the container changes in phase to a gaseous phase from a liquid phase by receiving heat from the heating element, the primary refrigerant that changes in phase to the gaseous phase changes in phase to a liquid phase from the gaseous phase by the condensation tube through which the secondary refrigerant flows, and which penetrates through the gaseous phase portion in the inside of the container, and latent heat released from the primary refrigerant at the time of the phase change is transferred to the secondary refrigerant flowing through the condensation tube. The secondary refrigerant receiving the latent heat from the primary refrigerant flows through the condensation tube to the outside from the inside of the cooling device, and thereby the latent heat is transported to the outside of the cooling device. The secondary refrigerant receiving the latent heat is cooled in the secondary refrigerant cooling portion provided in the outside of the cooling device. Further, in an aspect of the cooling device in the above described [19], the tertiary refrigerant sealed in the inside of the second container of the heat transport member changes in phase to a gaseous phase from a liquid phase by receiving heat from the heating element, the tertiary refrigerant that changes in phase to a gaseous phase flows to the inner direction of the extended portion from the inside of the second container, and changes in phase to a liquid phase from a gaseous phase by a heat exchange action with the primary refrigerant sealed in the inside of the first container. The latent heat released from the tertiary refrigerant at the time of the phase change is transferred to the primary refrigerant sealed in the inside of the first container. The primary refrigerant changes in phase to a gaseous phase from a liquid phase by receiving latent heat from the tertiary refrigerant, the primary refrigerant that changes in phase to a gaseous phase changes in phase to a liquid phase from a gaseous phase by the condensation tube through which the secondary refrigerant flows, and which penetrates through the gaseous phase portion in the inside of the first container, and the latent heat released from the primary refrigerant at the time of the phase change is transferred to the secondary refrigerant flowing through the condensation tube. The secondary refrigerant receiving latent heat from the primary refrigerant flows through the condensation tube to the outside from the inside of the cooling device, and thereby the latent heat is transported to the outside of the cooling device. The secondary refrigerant receiving the latent heat is cooled in the secondary refrigerant cooling portion provided in the outside of the cooling device.

Note that in the present description, “plan view” means a state of visual recognition from above in the direction of gravity.

According to an aspect of the cooling device of the present disclosure, excellent cooling characteristics can be exhibited while avoiding increase in size of the device by including the primary refrigerant sealed in the inside of the container, and the condensation tube through which the secondary refrigerant flows, and which penetrates through the gaseous phase portion in the inside of the container.

According to an aspect of the cooling device of the present disclosure, the heating element is thermally connected to the part where the primary refrigerant in a liquid phase exists or a vicinity of the part, on the outer surface of the container, and thereby heat resistance to the primary refrigerant from the heating element can be reduced.

According to an aspect of the cooling device of the present disclosure, the container inner surface area increasing portion that increases the contact area with the primary refrigerant in a liquid phase is formed on the inner surface of the container to which the heating element is thermally connected, and thereby heat transfer to the primary refrigerant from the heating element through the container is made smooth. Accordingly, phase change of the primary refrigerant to a gaseous phase from a liquid phase is promoted, and cooling characteristics are more improved.

According to an aspect of the cooling device of the present disclosure, at east a part of the container inner surface area increasing portion is a sintered body of a thermal conductive material or an aggregate of a particulate thermal conductive material, and thereby the porous portion is formed in the container inner surface area increasing portion, so that phase change of the primary refrigerant to a gaseous phase from a liquid phase is further promoted, and cooling characteristics are further improved.

According to an aspect of the cooling device of the present disclosure, the condensation tube outer surface area increasing portion that increases the contact area with the primary refrigerant of a gaseous phase is formed on the outer surface of the condensation tube, whereby the heat exchange action of the condensation tube is improved, and phase change of the primary refrigerant to a liquid phase from a gaseous phase is promoted. Accordingly, heat transfer from the primary refrigerant to the secondary refrigerant is more promoted, and cooling characteristics are further improved.

According to an aspect of the cooling device of the present disclosure, the condensation tube inner surface area increasing portion that increases the contact area with the secondary refrigerant is formed on the inner surface of the condensation tube, whereby the heat exchange action of the condensation tube is improved, and heat transfer from the primary refrigerant to the secondary refrigerant is more promoted.

### BRIEF DESCRIPTION OF THE DRAWINGS

FIG. 1 is a perspective view explaining an outline of a cooling device according to a first embodiment of the present disclosure;

FIG. 2 is a perspective view explaining an outline of a cooling device according to a second embodiment of the present disclosure;

FIG. 3 is a perspective view explaining an outline of a cooling device according to a third embodiment of the present disclosure;

FIG. 4A is an explanatory view of an enlarged outer surface of a condensation tube provided in the cooling device according to the third embodiment of the present disclosure, and FIG. 4B is an explanatory view of an enlarged inner surface of the condensation tube provided in the cooling device according to the third embodiment of the present disclosure;

FIG. 5 is a sectional side view explaining an outline of a cooling device according to a fourth embodiment of the present disclosure;

FIG. 6A is a sectional side view explaining an outline of a cooling device according to a fifth embodiment of the present disclosure, and FIG. 6B is a sectional front view explaining an outline of the cooling device according to the fifth embodiment of the present disclosure;

FIG. 7 is a sectional side view explaining an outline of a cooling device according to a sixth embodiment of the present disclosure;

FIG. 8 is a perspective view explaining an outline of a cooling device according to a seventh embodiment of the present disclosure;

FIG. 9 is a sectional side view explaining an outline of a cooling device according to an eighth embodiment of the present disclosure;

FIG. 10 is a sectional plan view explaining the outline of the cooling device according to the eighth embodiment of the present disclosure; and

FIG. 11 is a sectional side view explaining an outline of a cooling device according to a ninth embodiment of the present disclosure.

### DETAILED DESCRIPTION

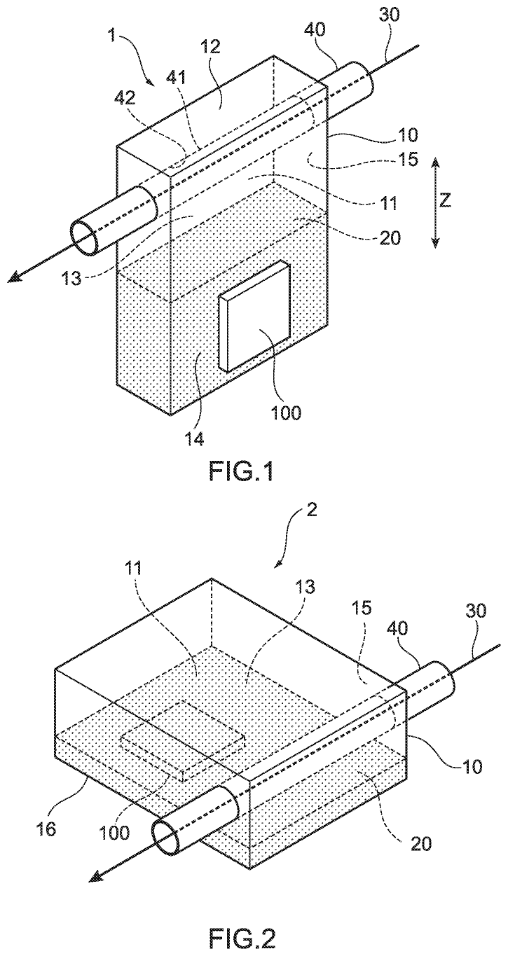

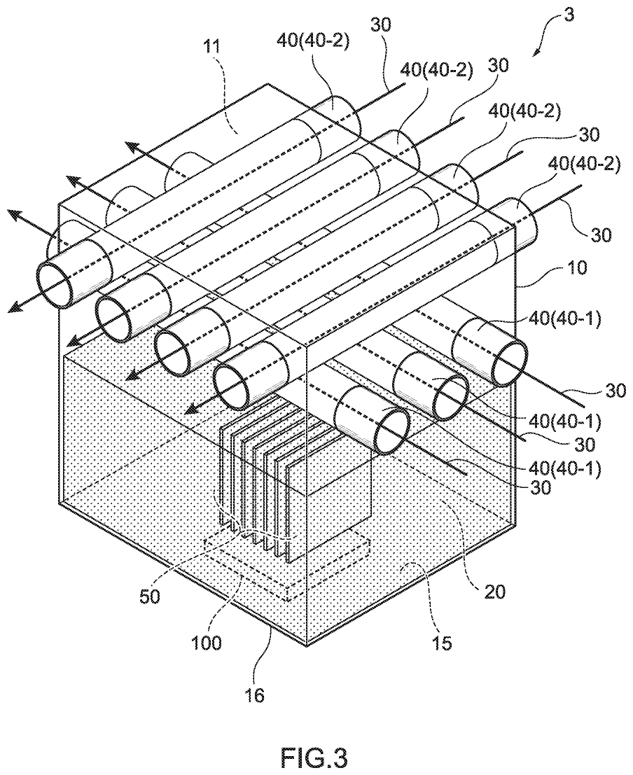

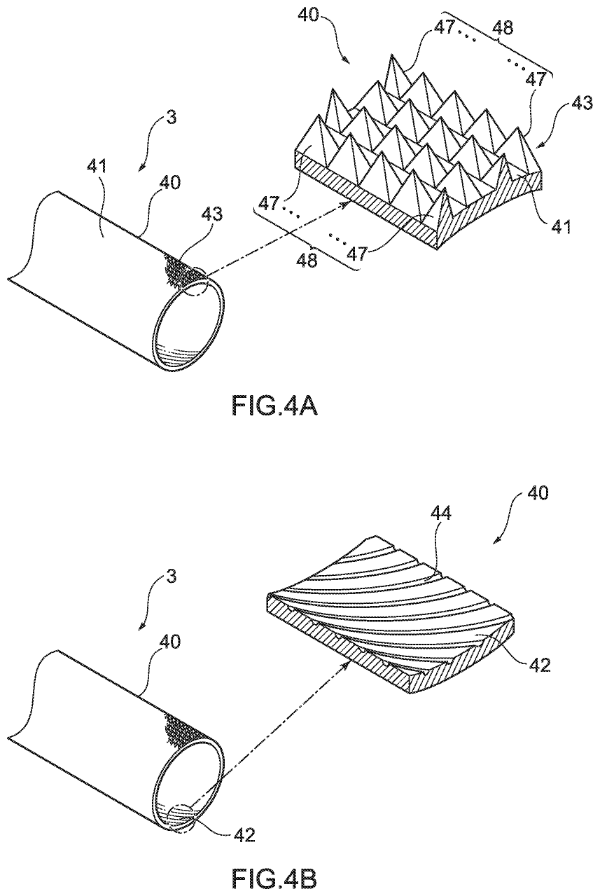

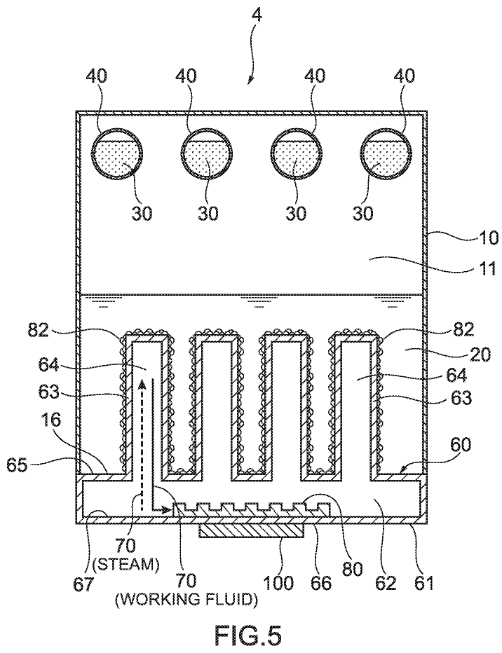

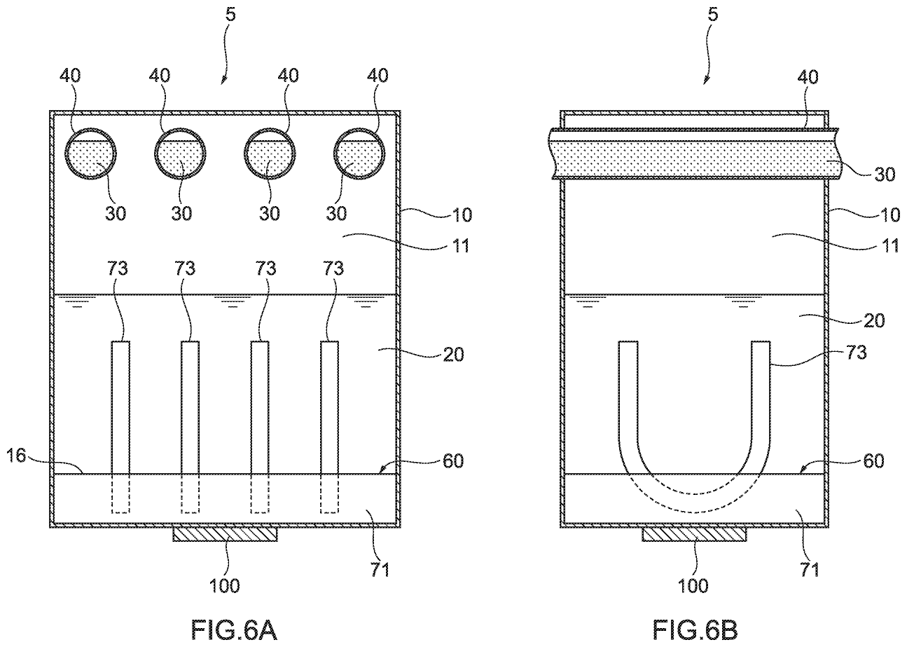

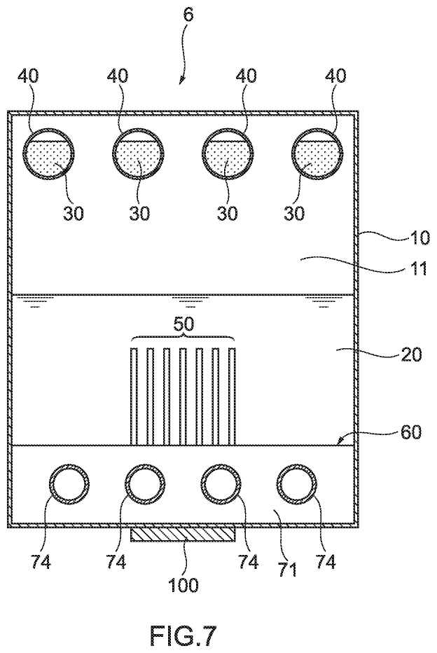

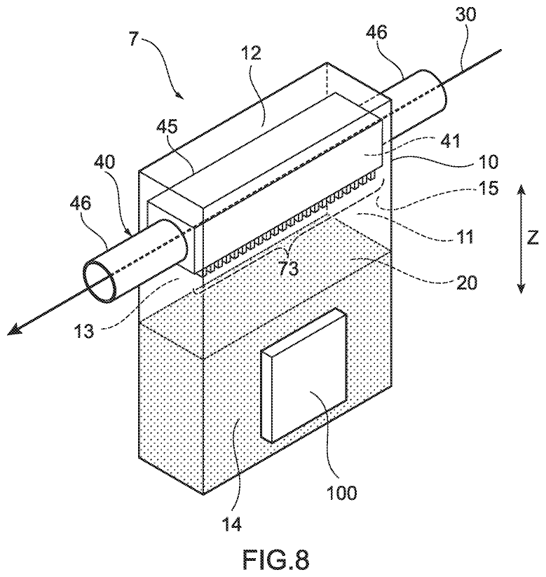

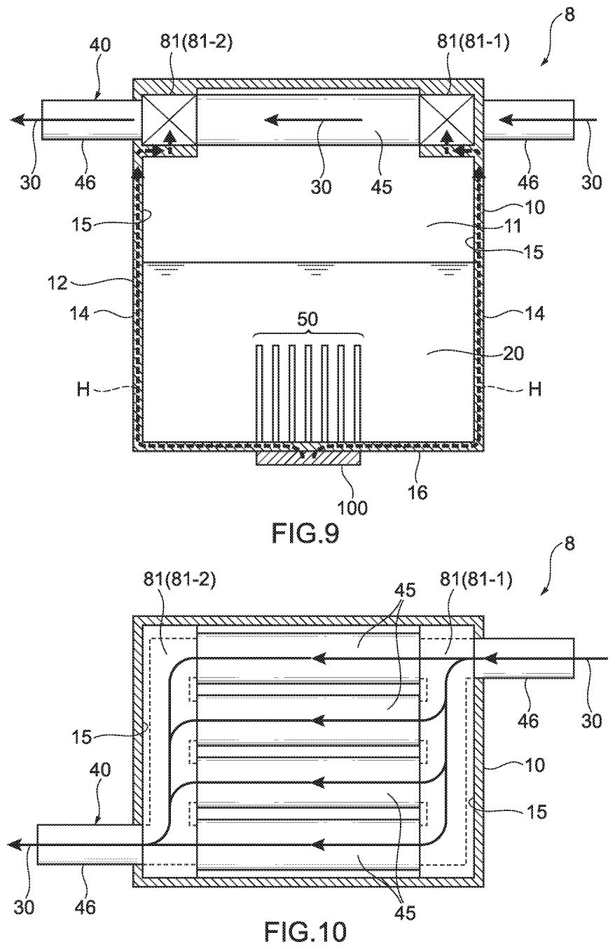

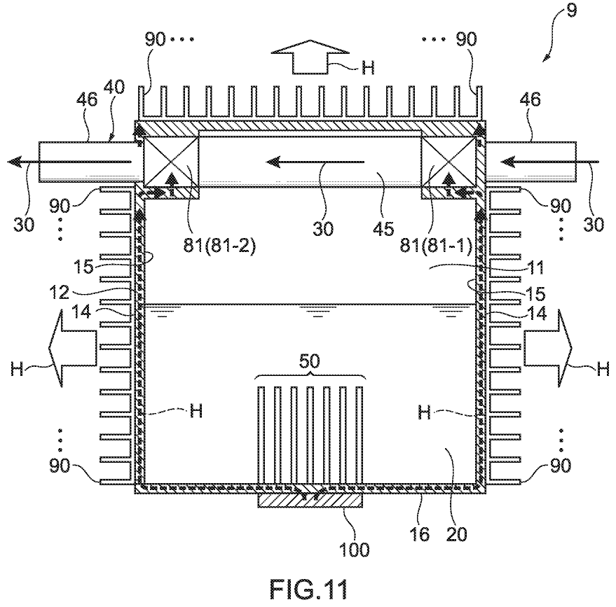

Hereinafter, a heat sink according to embodiments of the present disclosure will be described with use of the drawings. FIG. 1 is a perspective view explaining an outline of a cooling device according to a first embodiment of the present disclosure. FIG. 2 is a perspective view explaining an outline of a cooling device according to a second embodiment of the present disclosure. FIG. 3 is a perspective view explaining an outline of a cooling device according to a third embodiment of the present disclosure. FIG. 4A is an explanatory view of an enlarged outer surface of a condensation tube provided in the cooling device according to the third embodiment of the present disclosure, and FIG. 4B is an explanatory view of an enlarged inner surface of the condensation tube provided in the cooling device according to the third embodiment of the present disclosure. FIG. 5 is a sectional side view explaining an outline of a cooling device according to a fourth embodiment of the present disclosure. FIG. 6A is a sectional side view explaining an outline of a cooling device according to a fifth embodiment of the present disclosure, and FIG. 6B is a sectional front view explaining an outline of the cooling device according to the fifth embodiment of the present disclosure. FIG. 7 is a sectional side view explaining an outline of a cooling device according to a sixth embodiment of the present disclosure. FIG. 8 is a perspective view explaining an outline of a cooling device according to a seventh embodiment of the present disclosure. FIG. 9 is a sectional side view explaining an outline of a cooling device according to an eighth embodiment of the present disclosure. FIG. 10 is a sectional plan view explaining the outline of the cooling device according to the eighth embodiment of the present disclosure. FIG. 11 is a sectional side view explaining an outline of a cooling device according to a ninth embodiment of the present disclosure.

First, the cooling device according to the first embodiment of the present disclosure will be descried. As illustrated in FIG. 1, a cooling device 1 according to the first embodiment of the present disclosure includes a container 10, a primary refrigerant 20 that is sealed into the inside of the container 10, and a condensation tube 40 through which a secondary refrigerant 30 flows, and which penetrates through a gaseous phase portion 11 in the inside of the container 10. A heating element 100 that is an object to be cooled is thermally connected to an outer surface 12 of the container 10, and thereby the heating element 100 is cooled.

A hollow cavity portion 13 is formed in the inside of the container 10. The cavity portion 13 is a space sealed to an external environment, and is depressurized by degassing. A shape of the container 10 is a rectangular parallelepiped and has a longitudinal direction Z. The cooling device 1 is installed so that the longitudinal direction Z of the container 10 is along a direction of gravity. Accordingly, in the cooling device 1, the container 10 in a rectangular parallelepiped shape is installed in an upright state. Further, in the cooling device 1 in which the container 10 in a rectangular parallelepiped shape is in the upright state, the heating element 100 is thermally connected to a side surface 14 of the container 10 in the upright state. The cooling device 1 is effective when it is necessary to install the cooling device in a space which is narrow in a width direction.

Further, as illustrated in FIG. 1, in the cavity portion 13, a predetermined amount of the primary refrigerant 20 in a liquid phase is stored. The primary refrigerant 20 in the liquid phase is stored in such a volume that the gaseous phase portion 11 can be formed in the inside of the container 10. The primary refrigerant 20 in a liquid phase exists at a lower side in the direction of gravity, of the cavity portion 13, and the gaseous phase portion 11 in which the primary refrigerant 20 in the liquid phase is not stored is formed at an upper side in the direction of gravity of the cavity portion 13. A connection position of the heating element 100 is not specially limited, but in the cooling device 1, the heating element 100 is thermally connected to a part where the primary refrigerant 20 in a liquid phase exists, on the outer surface 12 of the container 10. By adopting the above described part as the connection position of the heating element 100 to the container 10, heat transfer from the heating element 100 to the primary refrigerant 20 in a liquid phase is smoothly performed, and thermal resistance to the primary refrigerant 20 from the heating element 100 can be reduced. In a region corresponding to the part to which the heating element 100 is thermally connected, of an inner surface 15 of the container 10, a part (container inner surface area increasing portion) that increases a surface area of the inner surface 15 of the container 10, such as protrusions and recesses may be formed, or the region may be a flat surface. In FIG. 1, for convenience, the inner surface 15 of the container 10 is a flat surface.

The condensation tube 40 is a tubular member, and penetrates through the gaseous phase portion 11 in the inside of the container 10. The condensation tube 40 is located upward in the direction of gravity, of the inner surface 15 of the container 10 in the part to which the heating element 100 is thermally connected. An inner space of the condensation tube 40 does not communicate with the inside (the cavity portion 13) of the container 10. In other words, the inner space of the condensation tube 40 is a space that does not communicate with the gaseous phase portion 11, and is independent from the gaseous phase portion 11. Further, the condensation tube 40 does not contact the primary refrigerant 20 in a liquid phase that is stored at the lower side in the direction of gravity. In other words, the primary refrigerant 20 in a liquid phase does not contact the condensation tube 40 in which the secondary refrigerant is stored. On an outer surface 41 of the condensation tube 40, a part (condensation tube outer surface area increasing portion) that increases a surface area of the outer surface 41 of the condensation tube 40 such as recesses and protrusions may be formed, or the outer surface 41 may be a smooth surface. Further, on an inner surface 42 of the condensation tube 40, a part (condensation tube inner surface area increasing portion) that increases a surface area of the inner surface 42 of the condensation tube 40 such as recesses and protrusions may be formed, or the inner surface 42 may be a smooth surface. In FIG. 1, for convenience, both the outer surface 41 of the condensation tube 40 and the inner surface 42 of the condensation tube 40 are smooth surfaces.

Of the container 10, in a part corresponding to the gaseous phase portion 11, a through-hole is formed, and the condensation tube 40 is inserted through the through-hole, and thereby the condensation tube 40 is mounted to the container 10 while keeping a sealed state of the cavity portion 13. While a number of the condensation tubes 40 is not specially limited, the single condensation tube 40 is mounted in the cooling device 1. A sectional shape in a radial direction of the condensation tube 40 is substantially circular.

In the condensation tube 40, the secondary refrigerant 30 in a liquid phase flows in a fixed direction along an extending direction of the condensation tube 40. Accordingly, the secondary refrigerant 30 flows to penetrate through the gaseous phase portion 11 via a wall surface of the condensation tube 40. The secondary refrigerant 30 is cooled to a liquid temperature which is lower than an allowable maximum temperature of the heating element 100, for example.

A material of the container 10 is not specially limited, but a wide range of materials can be used, and for example, copper, a copper alloy, aluminum, an aluminum alloy, nickel, a nickel alloy, stainless steel, titanium, a titanium alloy and the like can be cited. A material of the condensation tube 40 is not specially limited, and, for example, copper, a copper alloy, aluminum, an aluminum alloy, nickel, a nickel alloy, stainless steel, titanium, a titanium alloy and the like can be cited. The primary refrigerant is not specially limited, but a wide range of materials can be used, and for example, an electrically insulating refrigerant can be cited. As specific examples, for example, water, fluorocarbons, cyclopentane, ethylene glycol, a mixture of these substances and the like can be cited. Among the primary refrigerants, from viewpoint of electrical insulation, fluorocarbons, cyclopentane, and ethylene glycol are preferable, and fluorocarbons are specially preferable. The secondary refrigerant is not specially limited, and, for example, water, antifreeze (main component is, for example, ethylene glycol) and the like can be cited.

Next, an operation of the cooling device 1 according to the first embodiment and a cooling system using the cooling device 1 will be described. First, the operation of the cooling device 1 will be described.

The primary refrigerant 20 in a liquid phase stored in the cavity portion 13 of the container 10 receives heat from the heating element 100, thereby changes in phase from the liquid phase to a gaseous phase, and absorbs the heat from the heating element 100 as latent heat. The primary refrigerant that changes in phase to the gaseous phase moves upward in the direction of gravity in the inner space of the container 10, and flows into the gaseous phase portion 11 of the container 10. On the other hand, in the condensation tube 40 penetrating through the gaseous phase portion 11, the secondary refrigerant 30 having a low temperature flows. The secondary refrigerant 30 with a low temperature flows through the condensation tube 40, and thereby the condensation tube 40 disposed in the gaseous phase portion 11 exhibits a heat exchange action. The primary refrigerant which changes in phase to the gaseous phase contacts or approaches the outer surface 41 of the condensation tube 40, thereby releases the latent heat by the heat exchange action of the condensation tube 40, and changes in phase to a liquid phase from the gaseous phase. The latent heat released from the primary refrigerant at the time of phase change to the liquid phase from the gaseous phase is transferred to the secondary refrigerant 30 that flows through the condensation tube 40. Further, the primary refrigerant which changes in phase to the liquid phase returns to a lower side in the direction of gravity from the gaseous phase portion 11 as the primary refrigerant 20 in the liquid phase, by a gravity action. From the above description, the primary refrigerant 20 repeats phase change to the gaseous phase from the liquid phase and to the liquid phase from the gaseous phase in the inner space of the container 10. In the cooling device 1, the gaseous phase portion 11 of the container 10 has a predetermined volume, and therefore, it is not necessary to form a circulation path of the primary refrigerant 20 like a partition plate when the primary refrigerant 20 repeats phase change from the liquid phase to the gaseous phase and to the liquid phase from the gaseous phase in the inner space of the container 10. Accordingly, it is possible to simplify a structure of the container 10. The secondary refrigerant 30 that receives heat from the primary refrigerant flows from the inside to the outside of the cooling device 1 along the extending direction of the condensation tube 40, and thereby heat of the heating element 100 is transported to the outside of the cooling device 1.

Next, the cooling system using the cooling device 1 according to the first embodiment will be described. In the cooling system using the cooling device 1, the cooling device 1, and a secondary refrigerant cooling portion (not illustrated) to which the condensation tube 40 extending from the cooling device 1 are used. Further, in the above described cooling system, a circulation path of the condensation tube 40 in which the condensation tube 40 circulates in a loop shape in the cooling device 1 and the secondary refrigerant cooling portion is formed. The secondary refrigerant 30 receiving heat from the primary refrigerant flows through the condensation tube 40 from the cooling device 1 to the secondary refrigerant cooling portion, and is cooled to a predetermined liquid temperature, for example, a liquid temperature lower than the allowable maximum temperature of the heating element 100, for example, in the secondary refrigerant cooling portion. The secondary refrigerant 30 which is cooled in the secondary refrigerant cooling portion flows through the condensation tube 40, returns to the cooling device 1 from the secondary refrigerant cooling portion, and exhibits a heat exchange action in the gaseous phase portion 11 of the cooling device 1. Accordingly, the secondary refrigerant 30 circulates in the loop shape in the cooling device 1 and the secondary refrigerant cooling portion, and thereby the secondary refrigerant 30 which is cooled is continuously supplied to a region of the gaseous phase portion 11.

Next, a cooling device according to a second embodiment of the present disclosure will be described. Note that same components as the components of the cooling device according to the first embodiment will be described by using the same reference signs.

In the cooling device 1 according to the first embodiment, the container 10 is installed upright so that the longitudinal direction Z of the container 10 is along the direction of gravity, and the heating element 100 is thermally connected to the side surface 14 of the container 10 in the upright state. Instead of this, as illustrated in FIG. 2, in a cooling device 2 according to the second embodiment, a container 10 is a flat type, the rectangular parallelepiped container 10 is horizontally placed so that a plane direction of the container 10 is substantially in an orthogonal direction to the direction of gravity, and the heating element 100 is thermally connected to a bottom surface 16 of the container 10 in a posture horizontally placed. Note that a mounting position of a condensation tube 40 is not specially limited, and in the cooling device 2, the condensation tube 40 is mounted to a position where the condensation tube 40 does not overlap the heating element 100 in plan view.

The cooling device 2 is effective when it is necessary to install the cooling device in a space which is narrow in a height direction. While the heating elements may be loaded at high density, the cooling device of the present disclosure can be installed not only in a space narrow in a width direction but also in a space narrow in a height direction in this way.

Next, a cooling device according to a third embodiment of the present disclosure will be described. Note that same components as the components in the cooling devices according to the first and the second embodiments will be described by using the same reference signs.

As illustrated in FIG. 3, in a cooling device 3 according to the third embodiment, in a region corresponding to a part to which the heating element 100 is thermally connected, in an inner surface 15 of a container 10, a container inner surface area increasing portion 50 that is a part that increases a surface area of the inner surface 15 of the container 10, such as protrusions and recesses, is formed. Since the container inner surface area increasing portion 50 is formed, a contact area of the inner surface 15 of the container 10 and a primary refrigerant 20 in a liquid phase increases, in the region corresponding to the part to which the heating element 100 is thermally connected, in the inner surface 15 of the container 10. Accordingly, by the container inner surface area increasing portion 50, heat transfer to the primary refrigerant 20 in a liquid phase from the heating element 100 via the container 10 is performed smoothly. As a result, phase change to a gaseous phase from a liquid phase of the primary refrigerant 20 is promoted, and cooling characteristics of the cooling device 3 are more improved.

The container inner surface area increasing portion 50 is immersed in the primary refrigerant in a liquid phase stored in the container 10. Accordingly, the container inner surface area increasing portion 50 directly contacts the primary refrigerant 20 in a liquid phase. The entire container inner surface area increasing portion 50 may be immersed in the primary refrigerant 20 in a liquid phase, or a part of the container inner surface area increasing portion 50 may be immersed in the primary refrigerant 20. Note that in the cooling device 3, the entire container inner surface area increasing portion 50 is immersed in the primary refrigerant 20 in a liquid phase.

The container inner surface area increasing portion 50 can be provided by molding of the container 10 by using a molding die, or by mounting a separate member from the container 10 to the inner surface 15 of the container 10, for example. As a mode of the container inner surface area increasing portion 50, for example, protruded and recessed portions formed on the inner surface 15 of the container 10 can be cited, for example, and as specific examples, plate-shaped fins and pin fins provided to be upright on the inner surface 15 of the container 10, dented portions, groove portions and the like formed on the inner surface 15 of the container 10 can be cited. As a forming method of the plate-shaped fins and pin fins, for example, methods of attaching plate-shaped fins, or pin fins that are additionally produced to the inner surface 15 of the container 10 by soldering, brazing, sintering or the like, a method of cutting the inner surface 15 of the container 10, an extruding method, an etching method and the like are cited. Further, as a forming method of the dented portions, and the groove portions, for example, a method of cutting the inner surface 15 of the container 10, an extruding method, an etching method and the like are cited. Note that in the cooling device 3, a plurality of square or rectangular plate-shaped fines are disposed in parallel as the container inner surface area increasing portion 50.

A material of the container inner surface area increasing portion 50 is not specially limited, and, for example, a thermal conductive member can be cited. As specific examples of the material of the container inner surface area increasing portion 50, a metal member (for example, copper, a copper alloy, aluminum, an aluminum alloy, stainless steel and the like), and a carbon member (for example, graphite and the like) can be cited. Further, at least a part of the container inner surface area increasing portion 50 may be formed of a sintered body of a thermal conductive material, or an aggregate of a particulate thermal conductive material, and may be formed of, for example, a metal sintered body or an aggregate of carbon particles. The metal sintered body and the aggregate of carbon particles may be provided on a surface portion of the container inner surface area increasing portion 50, for example. More specifically, for example, a sintered body of a thermal conductive material such as a metal sintered body, or an aggregate of a particulate thermal conductive material such as an aggregate of carbon particles and/or metal powder may be formed in layers on surface portions of the plate-shaped fins, or the pin fins provided to be upright on the inner surface 15 of the container 10, and dented portions, groove portions or the like formed on the inner surface 15 of the container 10. A porous portion is formed in the container inner surface area increasing portion 50 because at least a part of the container inner surface area increasing portion 50 is formed of a sintered body of a thermal conductive material, or an aggregate of a particulate thermal conductive material, so that phase change of the primary refrigerant 20 from a liquid phase to a gaseous phase is further promoted, and the cooling characteristics of the cooling device 3 are further improved. When the container inner surface area increasing portion 50 is formed of the sintered body of a thermal conductive material, or an aggregate of a particulate thermal conductive material, the entire container inner surface area increasing portion 50 becomes a porous body, and the primary refrigerant in a gaseous phase is generated and stays in the porous body, so that thermal conductivity from the container inner surface area increasing portion 50 to the primary refrigerant 20 in the liquid phase may not sufficiently be obtained. However, since the sintered body of the thermal conductive material, or the aggregate of the particulate thermal conductive material are formed in layers on the surface portions of the plate-shaped fins, pin fins, the dented portions, the groove portions or the like, the thermal conductivity from the container inner surface area increasing portion 50 to the primary refrigerant 20 in a liquid phase is improved while phase change from the liquid phase to the gaseous phase of the primary refrigerant 20 is further promoted, and as a result, the cooling characteristics of the cooling device 3 are further improved. As the material of the metal sintered body, for example, metal powder, metal fiber, metal mesh, metal braid, metal foil and the like can be cited. These metal materials may be used individually, or in combination of two or more. Further, a kind of metal of the metal sintered body is not specially limited, and, for example, copper, a copper alloy and the like can be cited. The metal sintered body can be formed by heating a metal material by heating means such as a furnace. Further, by thermally spraying metal powder to a surface, an aggregate of a particulate thermal conductive material that is in a coating film form having fine protrusions and recesses can be formed. Further, an aggregate of a particulate thermal conductive material may be formed by melting and forming metal powder by laser or the like. Further, carbon particles forming the aggregate of carbon particles is not specially limited, and for example, carbon nano particles, carbon black and the like can be cited.

Further, in the cooling devices according to the first and second embodiments, a number of condensation tubes is one, but instead of this, as illustrated in FIG. 3, in the cooling device 3 according to the third embodiment, a plurality of condensation tubes 40, 40 . . . are provided. In the cooling device 3, the plurality of condensation tubes 40, 40 . . . are disposed in layers. In the cooling device 3, the condensation tubes 40 are disposed in multiple layers (two layers in FIG. 3), a plurality of first condensation tubes 40-1, 40-1 . . . that are disposed on a liquid-phase primary refrigerant 20 side, and a plurality of second condensation tubes 40-2, 40-2 . . . that are disposed above the first condensation tubes 40-1 in the direction of gravity are provided. The plurality of first condensation tubes 40-1, 40-1 . . . are disposed in parallel with one another on a substantially same plane, and the plurality of second condensation tubes 40-2, 40-2, . . . are disposed in parallel with one another on a substantially same plane.

Further, an extending direction of the first condensation tube 40-1 in the gaseous phase portion 11 of the container 10 may be same as or different from an extending direction of the second condensation tube 40-2, but in the cooling device 3, the extending direction of the first condensation tube 40-1 is different from the extending direction of the second condensation tube 40-2. In the gaseous phase portion 11, the extending direction of the first condensation tube 40-1 is substantially an orthogonal direction to the extending direction of the second condensation tube 40-2.

In the cooling device 3, the heating element 100 is thermally connected to the bottom surface 16 of the container in the posture horizontally placed. The condensation tubes 40 have parts overlapping the heating element 100 in plan view.

As illustrated in FIG. 4A, in the cooling device 3, a condensation tube outer surface area increasing portion 43 that increases a contact area with the primary refrigerant in a gaseous phase is formed by increasing a surface area of an outer surface 41 of the condensation tube 40 such as recesses and protrusions is formed on an outer surface 41 of the condensation tube 40. The condensation tube outer surface area increasing portion 43 is formed, whereby the heat exchange action of the condensation tube 40 is improved, and phase change of the primary refrigerant from the gaseous phase to the liquid phase is promoted. As a result, heat transfer from the primary refrigerant 20 to the secondary refrigerant 30 is more promoted, and the cooling characteristics of the cooling device 3 are further improved. The condensation tube outer surface area increasing portion 43 may be formed on the entire outer surface 41 that contacts the primary refrigerant in a gaseous phase, or may be formed only on a region (for example, a lower side in the direction of gravity of the outer surface 41) of a part of the outer surface 41.

The condensation tube outer surface area increasing portion 43 can be provided, for example, by molding of the condensation tube 40 using a molding die, or mounting a separate member from the condensation tube 40 on the outer surface 41 of the condensation tube 40. A mode of the condensation tube outer surface area increasing portion 43 is not specially limited, and a plurality of projections formed on the outer surface 41 of the condensation tube 40, a plurality of grooves, dents or the like formed on the outer surface 41 of the condensation tube 40 can be cited. A forming method of the projections is not specially limited, and, for example, a method of mounting projections separately produced on the outer surface 41 of the condensation tube 40 by soldering, brazing, sintering or the like, a method of cutting the outer surface 41 of the condensation tube 40, a method of etching and the like are cited. A forming method of the dented portions, and grooves is not specially limited, and, for example, a method of cutting the outer surface 41 of the condensation tube 40, a method of etching and the like are cited. In the condensation tube outer surface area increasing portion 43 in FIG. 4A, conical projections 47 are disposed in a staggered manner on the outer surface 41. More specifically, in the condensation tube outer surface area increasing portion 43 in FIG. 4A, a shape of the projection 47 is a quadrangular pyramid. In the condensation tube outer surface area increasing portion 43, a projection row 48 is formed by a plurality of projections 47 being linearly disposed in parallel in a longitudinal direction of the condensation tube 40, and a plurality of projection rows 48 are disposed in parallel along a circumferential direction of the condensation tube 40. Further, in the adjacent projection rows 48, positions of the projections 47 are displaced from one another by a predetermined amount, so that the projections 47 are disposed in a staggered manner. By adopting the condensation tube outer surface area increasing portion 43 as described above, surface tension of the outer surface 41 of the condensation tube 40 is reduced, and phase change to the liquid phase from the gaseous phase of the primary refrigerant is promoted more. In the condensation tube outer surface area increasing portion 43, the projections 47 are formed by a method of rolling, forging or cutting the outer surface 41, or a method of etching. In other words, the condensation tube outer surface area increasing portion 43 is integral with the condensation tube 40. The condensation tube outer surface area increasing portion 43 is formed by rolling, forging, cutting or etching the outer surface 41, whereby as compared with a mode of mounting projections separately produced on the outer surface 41 of the condensation tube 40, it is possible to reduce a space, and a size of the condensation tube 40, and it is possible to reduce a space and a size of the cooling device 3 by extension. Further, since it is possible to reduce the space and the size of the condensation tube 40, it is possible to provide more projections 47 per unit area of the outer surface 41 of the condensation tube 40, and as a result, phase change to the liquid phase from the gaseous phase of the primary refrigerant is more promoted.

Further, as illustrated in FIG. 4B, in the cooling device 3, a condensation tube inner surface area increasing portion 44 that increases a contact area of an inner surface 42 of the condensation tube 40 and the secondary refrigerant 30 by increasing a surface area of the inner surface 42 of the condensation tube 40, such as recesses and protrusions, is formed on the inner surface 42 of the condensation tube 40. The condensation tube inner surface area increasing portion 44 is formed, whereby the heat exchange action of the condensation tube 40 is improved, and heat transfer to the secondary refrigerant 30 from the primary refrigerant 20 is promoted more.

The condensation tube inner surface area increasing portion 44 can be provided, for example, by molding of the condensation tube 40 using a molding die, or mounting a separate member from the condensation tube 40 to the inner surface 42 of the condensation tube 40. A mode of the condensation tube inner surface area increasing portion 44 is not specially limited, and a plurality of projections formed on the inner surface 42 of the condensation tube 40, a plurality of grooves, dents or the like formed on the inner surface 42 of the condensation tube 40 can be cited. As a forming method of projections, for example, a method of mounting projections separately produced to the inner surface 42 of the condensation tube 40 by soldering, brazing, sintering or the like, a method of cutting the inner surface 42 of the condensation tube 40, a method of etching and the like are cited. Further, as a forming method of dent portions or the grooves, for example, a method of cutting the inner surface 42 of the condensation tube 40, a method of etching and the like are cited. In the condensation tube inner surface area increasing portion 44 in FIG. 4B, a plurality of grooves are spirally formed on the inner surface 42.

Next, a cooling device according to a fourth embodiment of the present disclosure will be described. Note that same components as the components in the cooling devices according to the first to the third embodiments will be described by using the same reference signs.

As illustrated in FIG. 5, in a cooling device 4 according to the fourth embodiment, as a bottom surface 16 of a container 10 (the first container 10 in the cooling device 4), a heat transport member 60 provided connectively to the first container 10 is provided. The heat transport member 60 has a second container 61 to which at least one heating element 100 is thermally connected, extended portions 63 each having an inner space 64 communicating with an inner space 62 of the second container 61, and a tertiary refrigerant 70 that is sealed in the inside of the heat transport member 60, that is, the inner space 62 of the second container 61 and the inner spaces 64 of the extended portions 63. The tertiary refrigerant 70 functions as a working fluid of the heat transport member 60. The tertiary refrigerant 70 is capable of flowing between the inner space 62 of the second container 61 and the inner spaces 64 of the extended portions 63. The inner space 62 of the second container 61 and the inner spaces 64 of the extended portions 63 are spaces sealed to an external environment, and are in a state depressurized by degassing.

The second container 61 is of a planar type. Of an outer surface of the second container 61, an outer surface 65 opposing the condensation tube 40 contacts the primary refrigerant 20 of a liquid phase sealed in the inside of the first container 10. In the cooling device 4, the outer surface 65 of the second container 61 forms the bottom surface 16 of the first container 10. Further, the heating element 100 that is an object to be cooled is thermally connected to an outer surface 66 opposing the outer surface 65 of the second container 61, and thereby the heating element 100 is cooled.

A connection position of the heating element 100 on the outer surface 66 of the second container 61 is not specially limited, but, for example, the heating element 100 is thermally connected to a part where the tertiary refrigerant 70 in a liquid phase that is a working fluid exists, or a vicinity of the part where the tertiary refrigerant 70 of a liquid phase exists, on the outer surface 66 of the second container 61. The connection position of the heating element 100 to the second container 61 is made the above described part, heat transport from the heating element 100 to the tertiary refrigerant 70 of a liquid phase is performed smoothly, and thermal resistance to the tertiary refrigerant 70 from the heating element 100 can be reduced.

Further, in a region corresponding to the part to which the heating element 100 is thermally connected, in an inner bottom surface 67 of the second container 61 to which the heating element 100 is thermally connected, a second container inner surface area increasing portion 80 that is a part that increases a surface area of the inner bottom surface 67 of the second container 61, such as protrusions and recesses, is formed. The second container inner surface area increasing portion 80 is formed, and thereby a contact area of the inner surface of the second container 61 and the tertiary refrigerant 70 in a liquid phase is increased in the region corresponding to the part to which the heating element 100 is thermally connected, in the inner bottom surface 67 of the second container 61. Accordingly, by the second container inner surface area increasing portion 80, heat transfer to the tertiary refrigerant 70 in a liquid phase from the heating element 100 via the second container 61 is performed smoothly. As a result, phase change to the gaseous phase from the liquid phase of the tertiary refrigerant 70 is promoted, and cooling characteristics of the cooling device 4 are further improved.

The second container inner surface area increasing portion 80 can be provided by, for example, molding of the second container 61 using a molding die, or by mounting a separate member from the second container 61 to the inner bottom surface 67 of the second container 61. As a mode of the second container inner surface area increasing portion 80, for example, protruded and recessed portions formed on the inner bottom surface 67 of the second container 61 can be cited, and as specific examples, plate-shaped fins or pin fins that are provided to be upright on the inner bottom surface 67 of the second container 61, dented portions, groove portions or the like formed on the inner bottom surface 67 of the second container 61 can be cited. As a forming method of the plate-shaped fins and the pin fins, for example, a method of mounting plate-shaped fins or pin fins that are separately produced to the inner bottom surface 67 of the second container 61 by soldering, brazing, sintering or the like, a method of cutting the inner bottom surface 67 of the second container 61, an extruding method, a method of etching and the like are cited. Further, as a forming method of the dented portions, and the groove portions, for example, a method of cutting the inner bottom surface 67 of the second container 61, an extruding method, a method of etching and the like are cited. Note that in the cooling device 4, as the second container inner surface area increasing portion 80, a plurality of plate-shaped fins are disposed in parallel.

A material of the second container inner surface area increasing portion 80 is not specially limited, and, for example, a thermal conductive member can be cited. As specific examples of the material of the second container inner surface area increasing portion 80, a metal member (for example, copper, a copper alloy, aluminum, an aluminum alloy, stainless steel or the like), a carbon member (for example, graphite or the like) can be cited. Further, at least a part of the second container inner surface area increasing portion 80 may be formed of a sintered body of a thermal conductive material, or an aggregate of a thermal conductive material, and may be formed of, for example, a metal sintered body, or an aggregate of carbon particles. The metal sintered body or the aggregate of carbon particles may be provided on a surface portion of the second container inner surface area increasing portion 80, for example. More specifically, for example, a sintered body of a thermal conductive material such as a metal sintered body or an aggregate of a particulate thermal conductive material such as an aggregate of carbon particles and/or metal powder may be formed in layers on surface portions of the plate-shaped fins or the pin fins provided to be upright on the inner bottom surface 67 of the second container 61, or the dented portions, the groove portions or the like formed on the inner bottom surface 67 of the second container 61. At least a part of the second container inner surface area increasing portion 80 is formed of the sintered body of a thermal conductive material or the aggregate of a particulate thermal conductive material, and thereby a porous portion is formed on the second container inner surface area increasing portion 80, so that the phase change of the tertiary refrigerant 70 to a gaseous phase from a liquid phase is further promoted, and the cooling characteristics of the cooling device 4 are further improved. When the second container inner surface area increasing portion 80 is formed of the sintered body of the thermal conductive material, or the aggregate of the particulate thermal conductive material, the entire second container inner surface area increasing portion 80 becomes a porous body, and the tertiary refrigerant 70 in the gaseous phase is generated and stays in the porous body, whereby thermal conductivity from the second container inner surface area increasing portion 80 to the tertiary refrigerant 70 in a liquid phase may not be sufficiently obtained. However, the sintered body of the thermal conductive material or the aggregate of the particulate thermal conductive material are formed in layers on the surface portions of the plate-shaped fins, pin fins, dented portions, the groove portions or the like, whereby thermal conductivity from the second container inner surface area increasing portion 80 to the tertiary refrigerant 70 in a liquid phase is improved while the phase change of the tertiary refrigerant 70 to a gaseous phase from a liquid phase is further promoted, and as a result, the cooling characteristics of the cooling device 4 are further improved. As the material of the metal sintered body, for example, metal powder, metal fiber, metal mesh, metal braid, metal foil and the like can be cited. These metal materials may be used individually, or may be used in combination of two or more. Further, a kind of metal of the metal sintered body is not specially limited, and, for example, copper, a copper alloy and the like can be cited. The metal sintered body can be formed by heating a metal material by heating means such as a furnace. Further, an aggregate of a particulate thermal conductive material, that is in a coating film form having fine protrusions and recesses can be formed by melt-spraying metal powder onto the surface. Further, an aggregate of a particulate thermal conductive material may be formed by melting and forming metal powder by laser or the like. Further, the carbon particles forming an aggregate of the carbon particles are not specially limited, and for example, carbon nano particles, carbon black and the like can be cited.

Further, on an inner surface of the second container 61, a wick structure (not illustrated) having a capillary force is provided. The tertiary refrigerant 70 that changes in phase from the gaseous phase to the liquid phase by releasing latent heat returns to the region corresponding to the part to which the heating element 100 is thermally connected, in the inner bottom surface 67 of the second container 61 by the capillary force of the wick structure.

As illustrated in FIG. 5, the extended portion 63 extends in a direction of the gaseous phase portion 11 in the inside of the first container 10 from the outer surface 65 of the second container 61. A mode of the extended portion 63 is not specially limited, and is a tubular body with an end portion on a gaseous phase portion 11 side closed in the cooling device 4. A shape of the extended portion 63 is not specially limited, and is a linear shape in the cooling device 4, and is provided to be upright perpendicularly to the outer surface 65 of the second container 61. Further, in the cooling device 4, a plurality of extended portions 63 are provided.

The inner space 64 of the extended portion 63 communicates with the inner space 62 of the second container 61. In other words, an end portion of the extended portion 63 on a second container 61 side is opened. Therefore, the inner space 64 of the extended portion 63 is in a state depressurized by degassing as in the inner space 62 of the second container 61. Note that in accordance with necessity, a wick structure having a capillary force may also be provided on an inner surface of the extended portion 63.

The extended portion 63 contacts the primary refrigerant 20 in a liquid phase which is sealed in the inside of the first container 10. In the cooling device 4, the entire extended portion 63 is in a state immersed in the primary refrigerant 20 in a liquid phase.

Further, a heat transport member outer surface area increasing portion 82 that increases a contact area with the primary refrigerant 20 in a liquid phase is formed on an outer surface of the extended portion 63. The heat transport member outer surface area increasing portion 82 is formed as recessed and protruded portions. The recessed and protruded portions of the heat transport member outer surface area increasing portion 82 may be formed of, for example, a sintered body of metal wire, a sintered body of metal powder or the like, or may be formed by etching or polishing. The heat transport member outer surface area increasing portion 82 is provided on the outer surface of the extended portion 63, whereby when the primary refrigerant 20 changes in phase from a liquid phase to a gaseous phase, fine bubble nucleus of the primary refrigerant 20 are easily formed, and phase change of the primary refrigerant 20 to the gaseous phase from the liquid phase is smoothly performed. The phase change of the primary refrigerant 20 to the gaseous phase from the liquid phase is smoothly performed, and thereby heat transfer to the primary refrigerant 20 from the tertiary refrigerant 70 is made smooth. Further, the heat transport member outer surface area increasing portion 82 is provided on the outer surface of the extended portion 63, whereby a gas layer including the primary refrigerant of the gaseous phase is prevented from growing along the outer surface of the extended portion 63, and therefore, heat transfer to the primary refrigerant 20 from the tertiary refrigerant 70 is made smooth.

Note that the heat transport member outer surface area increasing portion 82 may be formed on the outer surfaces of the extended portions 63 and the outer surface 65 of the second container 61, or may be formed on only the outer surface 65 of the second container 61.

Materials of the second container 61 and the extended portion 63 are not specially limited, a wide range of materials can be used, and, for example, copper, a copper alloy, aluminum, an aluminum alloy, nickel, a nickel alloy, stainless steel, titanium, a titanium alloy and the like can be cited. Further, the tertiary refrigerant 70 is not specially limited, and water, fluorocarbons, cyclopentane, ethylene glycol, mixtures of these substances and the like can be cited.

Next, an operation of the cooling device 4 according to the fourth embodiment will be described. When the second container 61 receives heat from the heating element 100, in the heat transport member 60, the tertiary refrigerant 70 in the liquid phase which is sealed in the inner space 62 of the second container 61 changes in phase to the gaseous phase from the liquid phase in the second container inner surface area increasing portion 80 and a vicinity of the second container inner surface area increasing portion 80, and flows in a steam path in the inner space 62 of the second container 61. Further, the tertiary refrigerant 70 in a gaseous phase flows into the inner space 64 of the extended portion 63 that communicates with the inner space 62 from the steam path of the inner space 62 of the second container 61. The tertiary refrigerant 70 in the gaseous phase that flows into the inner space 64 of the extended portion 63 releases latent heat in the inner space 64 of the extended portion 63, and changes in phase to a liquid phase from the gaseous phase. The latent heat which is released in the inner space 64 of the extended portion 63 is transferred to the primary refrigerant 20 in a liquid phase via a wall surface of the extended portion 63. The tertiary refrigerant 70 that changes in phase to a liquid phase from the gaseous phase in the inner space 64 of the extended portion 63 is returned to the second container 61 from the extended portion 63, and is returned to the second container inner surface area increasing portion 80 from the second container 61 in the wick structure provided in the second container 61.

The primary refrigerant 20 in a liquid phase which is sealed in the first container 10 receives heat from the tertiary refrigerant 70, thereby changes in phase to a gaseous phase from the liquid phase inside the container 10, and absorbs heat from the heating element 100 as latent heat. Thereafter, by a same operation as the operations of the above described cooling devices 1, 2 and 3, heat from the heating element 100 is transferred to the secondary refrigerant 30 which flows through the condensation tube 40 from the primary refrigerant 20, and the secondary refrigerant 30 that receives heat from the primary refrigerant 20 flows to the outside from the inside of the cooling device 4 along the extending direction of the condensation tube 40, whereby heat of the heating element 100 is transported to outside of the cooling device 4.

Next, in a cooling system using the cooling device 4 according to the fourth embodiment, the cooling device 4, and a secondary refrigerant cooling portion (not illustrated) to which the condensation tube 40 extending from the cooling device 4 is connected are used. Furthermore, in the above described cooling system, a circulation path of the condensation tube 40 in which the condensation tube 40 circulates in a loop shape between the cooling device 4 and the secondary refrigerant cooling portion is formed. The primary refrigerant 20 which receives heat from the tertiary refrigerant 70 changes in phase to a gaseous phase from the liquid phase inside of the first container 10, and the primary refrigerant in the gaseous phase changes in phase to a liquid phase from the gaseous phase by a heat exchange action of the condensation tube 40, whereby heat is transferred from the primary refrigerant to the secondary refrigerant 30 which flows through the condensation tube 40. The secondary refrigerant 30 that receives heat from the primary refrigerant flows through the condensation tube 40 to the secondary refrigerant cooling portion from the cooling device 4, and is cooled to a predetermined liquid temperature, for example, a liquid temperature lower than an allowable maximum temperature of the heating element 100, in the secondary refrigerant cooling portion. The secondary refrigerant 30 that is cooled in the secondary refrigerant cooling portion flows through the condensation tube 40 and returns to the cooling device 4 from the secondary refrigerant cooling portion, and exhibits a heat exchange action in the gaseous phase portion 11 of the cooling device 4. Accordingly, the secondary refrigerant 30 circulates in the loop shape between the cooling device 4 and the secondary refrigerant cooling portion, and thereby the secondary refrigerant 30 which is cooled is continuously supplied to the region of the gaseous phase portion 11.

Next, other embodiments of the cooling device of the present disclosure will be described. In the cooling device in each of the first to the third embodiments, the shape in plan view of the container is quadrangular, but the shape of the container is not specially limited, and for example, may be a polygon of a pentagon or more, a circle, an ellipse or a combination of these shapes. Further, in the cooling device according to the third embodiment, the container inner surface area increasing portion is formed in the region corresponding to the part to which the heating element is thermally connected, in the container inner surface, but instead of this, the container inner surface area increasing portion may be formed from the region corresponding to the part to which the heating element is thermally connected to a periphery edge of the region, or the container inner surface area increasing portion may be formed on an entire wall surface (the bottom surface of the container in the cooling device according to the third embodiment) to which the heating element is thermally connected, of the container.

Further, in the cooling device of each of the first to the third embodiments, the single heating element is thermally connected to the container, but a number of heating elements which are thermally connected to the container is not specially limited, and may be two or more. Further, in each of the above described embodiments, a sectional shape in the radial direction of the condensation tube is substantially circular, but a sectional shape in the radial direction of the condensation tube is not specially limited, and may be, for example, an elliptical shape, a flat shape, a quadrangular shape, a rounded rectangle or the like.

Further, in the cooling device of each of the first to the third embodiments, the heating element is thermally connected to the part where the primary refrigerant in the liquid phase exists, but instead of this, the heating element may be thermally connected to a vicinity of the part where the primary refrigerant in the liquid phase exists. In this case, the vicinity is the part where heat transfer from the heating element to the primary refrigerant in the liquid phase can be made smooth as in the part where the primary refrigerant in the liquid phase exists.

In the cooling device of the fourth embodiment, the heat transport member includes the second container, and the extended portions having the inner spaces that communicate with the inner space of the second container, but instead of this, the heat transport member may be a heat transport member that is not provided with the extended portions. In this case, the heat transport member is in a planar shape, and functions as a vapor chamber. Further, an outer shape opposing the condensation tube, of the outer surface of the second container of the heat transport member is in contact with the primary refrigerant in the liquid phase. Further, in the heat transport member which is not provided with the extended portion, a heat transport member outer surface area increasing portion that increases a contact area with the primary refrigerant n the liquid phase may be formed on the outer surface of the second container.

In a case of the heat transport member that is not provided with the extended portion, the tertiary refrigerant in the liquid phase which is sealed in the inner space of the second container changes in phase to the gaseous phase from the liquid phase in the second container inner surface area increasing portion and a vicinity of the second container inner surface area increasing portion, and diffuses in the inner space of the second container. The tertiary refrigerant in the gaseous phase releases latent heat in the inner space of the second container, and changes in phase to the liquid phase from the gaseous phase. The latent heat which is released in the inner space of the second container is transferred to the primary refrigerant in the liquid phase via the wall surface of the second container. The tertiary refrigerant changes in phase to a liquid phase from the gaseous phase in the inner space of the second container is returned to the second container inner surface area increasing portion from the second container, in the wick structure provided in the second container.

The primary refrigerant in the liquid phase that is sealed in the first container changes in phase to a gaseous phase from the liquid phase in the inside of the first container by receiving heat from the tertiary refrigerant, and absorbs heat from the heating element as latent heat. Thereafter, by a same action as in the above described respective cooling devices, heat from the heating element is transferred from the primary refrigerant to the secondary refrigerant flowing through the condensation tube, and the secondary refrigerant that receives heat from the primary refrigerant flows to the outside from the inside of the cooling device along the extending direction of the condensation tube, whereby heat of the heating element is transported to the outside of the cooling device.

In a cooling system of the cooling device using the heat transport member which is not provided with the extended portion, the cooling device and the secondary refrigerant cooling portion to which the condensation tube extending from the cooling device is connected are used. Further, in the above described cooling system, a circulation path of the condensation tube in which the condensation tube circulates in the loop shape between the cooling device and the secondary refrigerant cooling portion is formed. The primary refrigerant that receives heat from the tertiary refrigerant changes in phase to a gaseous phase from the liquid phase in the inside of the first container, and the primary refrigerant in the gaseous phase changes in phase to a liquid phase from the gaseous phase by the heat exchange action of the condensation tube, whereby heat is transferred to the secondary refrigerant that flows through the condensation tube from the primary refrigerant. The secondary refrigerant that receives heat from the primary refrigerant flows through the condensation tube from the cooling device to the secondary refrigerant cooling portion, and is cooled to a predetermined liquid temperature, for example, a liquid temperature lower than the allowable maximum temperature of the heating element in the secondary refrigerant cooling portion. The secondary refrigerant that is cooled in the secondary refrigerant cooling portion flows through the condensation tube and returns to the cooling device from the secondary refrigerant cooling portion, and exhibits a heat exchange action in the gaseous phase portion of the cooling device. Accordingly, the secondary refrigerant circulates in the loop shape between the cooling device and the secondary refrigerant cooling portion, and thereby the secondary refrigerant that is cooled is continuously supplied to the region of the gaseous phase portion.

In the cooling device of the fourth embodiment, the heat transport member includes the second container, but as illustrated in FIG. 6A and FIG. 6B, as a cooling device of a fifth embodiment, a cooling device 5 using a solid base block 71 instead of the second container may be adopted. In this case, an extended portion functions as a heat pipe portion 73, and a tertiary refrigerant is sealed in the inside of the heat pipe portion 73. The heat pipe portion 73 that is the extended portion is in a state provided to be upright on the base block 71. Further, the base block 71 is a plate-shaped member corresponding to a bottom surface 16 of a first container 10, and the base block 71 contacts a primary refrigerant 20 in a liquid phase.

A shape of a heat pipe forming the heat pipe portion 73 is not specially limited, and, for example, an L-shape, a U-shape, a linear shape and the like can be cited. In the cooling device 5, U-shaped heat pipes are provided to be upright on the base block 71. A material of the base block 71 is not specially limited, and a wide range of materials can be used, and, for example, a thermal conductive member, as a specific example, a metal member of copper, a copper alloy, aluminum, an aluminum alloy or the like can be cited. A mounting method of the heat pipe portion 73 to the base block 71 is not specially limited, and, for example, in the cooling device 5, it is possible to provide the heat pipe portion 73 on the base block 71 by providing a recessed portion in a thickness direction of the base block 71, and fitting a bottom portion of a U-shaped heat pipe in the recessed portion.

In the case of the heat transport member 60 including the solid base block 71 and the heat pipe portions 73, a base block 71 side of the heat pipe portion 73 functions as a heat receiving portion, and a part in contact with the primary refrigerant in the liquid phase functions as a heat radiating portion. When the heat receiving portion of the heat pipe portion 73 receives heat from the heating element 100 via the base block 71, a tertiary refrigerant in a liquid phase that is sealed in the inside of the heat pipe portion 73 changes in phase to a gaseous phase from the liquid phase in the heat receiving portion of the heat pipe portion 73, and the tertiary refrigerant in the gaseous phase flows to the heat radiating portion from the heat receiving portion of the heat pipe portion 73. The tertiary refrigerant in the gaseous phase releases latent heat in the heat radiating portion of the heat pipe portion 73, and changes in phase from the gaseous phase to a liquid phase. The latent heat released in the heat radiating portion of the heat pipe portion 73 is transferred to the primary refrigerant 20 in the liquid phase via the wall surface of the heat pipe portion 73. The tertiary refrigerant that changes in phase from the gaseous phase to the liquid phase in the inner space of the heat pipe portion 73 is returned to the heat receiving portion from the heat radiating portion of the heat pipe portion 73 in a wick structure (not illustrated) provided in the heat pipe portion 73.

In the cooling system of the cooling device 5 using the heat transport member 60 including the solid base block 71 and the heat pipe portions 73, the cooling device 5, and a secondary refrigerant cooling portion to which a condensation tube 40 extending from the cooling device 5 is connected are used, as described above. Further, in the above described cooling system, a circulation path of the condensation tube 40 in which the condensation tube 40 circulates in a loop shape between the cooling device 5 and the secondary refrigerant cooling portion is formed. The primary refrigerant 20 that receives heat from the tertiary refrigerant changes in phase to a gaseous phase from a liquid phase in the inside of the first container 10, and the primary refrigerant in the gaseous phase changes in phase to a liquid phase from the gaseous phase by the heat exchange action of the condensation tube 40, whereby heat is transferred from the primary refrigerant 20 to the secondary refrigerant 30 flowing through the condensation tube 40. The secondary refrigerant 30 that receives heat from the primary refrigerant 20 flows through the condensation tube 40 to the secondary refrigerant cooling portion from the cooling device 5, and is cooled to a predetermined liquid temperature, for example, a liquid temperature that is lower than an allowable maximum temperature of the heating element 100 in the secondary refrigerant cooling portion. The secondary refrigerant 30 that is cooled in the secondary refrigerant cooling portion flows through the condensation tube 40 to return to the cooling device 5 from the secondary refrigerant cooling portion, and exhibits a heat exchange action in the gaseous phase portion 11 of the cooling device 5. Accordingly, the secondary refrigerant 30 circulates in the loop shape between the cooling device 5 and the secondary refrigerant cooling portion, and thereby the secondary refrigerant 30 which is cooled is continuously supplied to the region of the gaseous phase portion 11.

Further, instead of the heat pipe portion 73 being provided to be upright on the base block 71, a cooling device 6 in which a heat pipe 74 is provided to be buried in the base block 71 may be adopted as a cooling device of a sixth embodiment, as illustrated in FIG. 7. In the cooling device 6, the entire heat pipe 74 is provided to be buried in the base block 71. Further, the heat pipe 74 extends along a plane direction (an orthogonal direction to a thickness direction of a base block 71) of the base block 71. Accordingly, the heat pipe 74 does not contact a primary refrigerant 20 in a liquid phase. A shape of the heat pipe 74 is not specially limited, and, for example, a linear shape can be cited.

As illustrated in FIG. 7, in the cooling device 6, a container inner surface area increasing portion 50 is formed on the base block 71. In the cooling device 6, the container inner surface area increasing portion 50 is formed by arranging a plurality of square or rectangular plate-shaped fins in parallel.

In a case of a heat transport member 60 including the solid base block 71 and the heat pipe 74, in the heat pipe 74, a part close to the heating element 100 functions as a heat receiving portion, and a part away from the heat receiving portion functions as a heat radiating portion. When the heat receiving portion of the heat pipe 74 receives heat from the heating element 100 via the base block 71, a tertiary refrigerant in a liquid phase that is sealed in the inside of the heat pipe 74 changes in phase to a gaseous phase from the liquid phase in the heat receiving portion of the heat pipe 74, and the tertiary refrigerant in the gaseous phase flows to the heat radiating portion from the heat receiving portion of the heat pipe 74. The tertiary refrigerant in the gaseous phase releases latent heat in the heat radiating portion of the heat pipe 74, and changes in phase to a liquid phase from the gaseous phase. Thereby, heat from the heating element 100 uniformly diffuses to the entire base block 71. The heat diffusing to the entire base block 71 is transferred to the primary refrigerant 20 in the liquid phase via the base block 71.

In a cooling system of the cooling device 6 using the heat transport member 60 including the solid base block 71 and the heat pipe 74, the cooling device 6, and a secondary refrigerant cooling portion to which the condensation tube 40 extending from the cooling device 6 is connected are used. Further, in the above described cooling system, a circulation path of the condensation tube 40 in which the condensation tube 40 circulates in a loop shape in the cooling device 6 and the secondary refrigerant cooling portion is formed. The primary refrigerant 20 that receives heat from the tertiary refrigerant changes in phase to a gaseous phase from the liquid phase in the inside of the first container 10, and the primary refrigerant in the gaseous phase changes in phase to a liquid phase from the gaseous phase by a heat exchange action of the condensation tube 40, whereby heat is transferred to the secondary refrigerant 30 flowing through the condensation tube 40 from the primary refrigerant 20. The secondary refrigerant 30 that receives heat from the primary refrigerant 20 flows through the condensation tube 40 from the cooling device 6 to the secondary refrigerant cooling portion, and is cooled to a predetermined liquid temperature, for example, a liquid temperature lower than an allowable maximum temperature of the heating element 100 in the secondary refrigerant cooling portion. The secondary refrigerant 30 that is cooled in the secondary refrigerant cooling portion flows through the condensation tube 40 to return to the cooling device 6 from the secondary refrigerant cooling portion, and exhibits a heat exchange action in the gaseous phase portion 11 of the cooling device 6. Accordingly, the secondary refrigerant 30 circulates in the loop shape in the cooling device 6 and the secondary refrigerant cooling portion, whereby the secondary refrigerant 30 which is cooled is continuously supplied to the region of the gaseous phase portion 11.

Next, a cooling device according to a seventh embodiment of the present disclosure will be described. Same components as the components in the cooling devices according to the first to the sixth embodiments will be described by using the same reference signs. As illustrated in FIG. 8, a cooling device 7 according to the seventh embodiment is in a mode where in the condensation tube 40, a shape in an orthogonal direction to a longitudinal direction of a condensation tube portion 45 in the inside of a container 10 is different from a shape in an orthogonal direction to a longitudinal direction, of a condensation tube portion 46 in an outside of the container 10.

In the cooling device 7, the shape in the orthogonal direction to the longitudinal direction of the condensation tube portion 45 in the inside the container 10 is a quadrangular shape, and the shape in the orthogonal direction to the longitudinal direction, of the condensation tube portion 46 in the outside of the container 10 is a circular shape. Accordingly, the condensation tube portion 45 in the inside of the container 10 is not in a tubular shape but in a rectangular parallelepiped shape. In the condensation tube 40, the condensation tube portion 45 in the inside of the container 10 and the condensation tube portion 46 in the outside of the container 10 are connected to each other, and inner spaces communicate with each other.

Further, in the cooling device 7, a condensation tube outer surface area increasing portion 73 that increases a contact area with a primary refrigerant 20 in a gaseous phase by increasing a surface area of an outer surface 41 of the condensation tube portion 45, such as recesses and protrusions, is formed on an outer surface 41, of the condensation tube portion 45 in the inside of the container 10. Since the condensation tube outer surface area increasing portion 73 is formed, a heat exchange action of the condensation tube 40 is improved, and phase change of the primary refrigerant 20 to a liquid phase from a gaseous phase is promoted. As a result, heat transfer to the secondary refrigerant 30 from the primary refrigerant 20 is more promoted, and cooling characteristics of the cooling device 7 are further improved. Note that in accordance with a usage situation of the cooling device 7, the condensation tube outer surface area increasing portion 73 does not have to be formed.

Note that for convenience of explanation, in the cooling device 7, parts except for the condensation tube 40 have same configurations as in the cooling device according to the first embodiment, but the parts except for the condensation tube 40 may have the same configurations as the configurations of the cooling devices according to the second to the sixth embodiments. Further, when a plurality of condensation tubes 40 are provided, the condensation tube portions 45, 45, 45 . . . in the inside of the container 10 may be independent from one another, that is, do not have to communicate with one another, or the condensation tube portions 45, 45, 45 . . . in the inside of the container 10 may communicate with one another and may be integrated, with respect to the respective condensation tubes 40, 40, 40 . . . .

Next, a cooling device according to an eighth embodiment of the present disclosure will be described. Same components as the components of the cooling devices according to the first to the seventh embodiments will be described by using the same reference signs. As illustrated in FIGS. 9 and 10, in a cooling device 8 according to the eight embodiment, a secondary refrigerant storing block 81 in which a secondary refrigerant 30 is stored is further provided in a condensation tube 40. Note that in the cooling device 8, parts except for the condensation tube 40 have a same configuration as the configuration of the cooling device according to the third embodiment, for convenience of explanation.

The secondary refrigerant storing block 81 is provided in the inside of a container 10. Further, the secondary refrigerant storing block 81 has a first secondary refrigerant storing block 81-1 connected to a secondary refrigerant 30 upstream side end portion (one end) of the condensation tube portion 45 in the inside of the container 10, and a second secondary refrigerant storing block 81-2 connected to a secondary refrigerant 30 downstream side end portion (another end) of the condensation tube portion 45 in the inside of the container 10, of the condensation tube 40. The secondary refrigerant storing block 81 is a hollow block member in both the first secondary refrigerant storing block 81-1 and the second secondary refrigerant storing block 81-2.

In the cooling device 8, of the condensation tube 40, a plurality (four in the cooling device 8) of the condensation tube portions 45 in the inside of the container 10 are provided, and the plurality of condensation tube portions 45, 45, 45 . . . in the inside of the container 10 are disposed in parallel with one another on a substantially same plane. On the other hand, in the cooling device 8, of the condensation tube 40, a number of the condensation tube portions 46 in an outside of the container 10 is one system (that is, one). From the above description, the condensation tube 40 is in a mode branched in the parts of the secondary refrigerant storing blocks 81.

As illustrated in FIGS. 9 and 10, the plurality of condensation tube portions 45, 45, 45 . . . in the inside of the container 10 respectively communicate with the first secondary refrigerant storing block 81-1 and the second secondary refrigerant storing block 81-2, and the first secondary refrigerant storing block 81-1 and the second secondary refrigerant storing block 81-2 respectively communicate with the condensation tube portion 46 in the outside of the container 10. From the above description, one ends of the plurality of condensation tube portions 45, 45, 45 . . . in the inside of the container 10 communicate with the condensation tube portion 46 in the outside of the container 10 via the first secondary refrigerant storing block 81-1. Further, the plurality of condensation tube portions 45, 45, 45 . . . in the inside of the container 10 communicate with one another via the first secondary refrigerant storing block 81-1. Other ends of the plurality of condensation tube portions 45, 45 45 . . . in the inside of the container 10 communicate with the condensation tube portion 46 in the outside of the container 10 via the second secondary refrigerant storing block 81-2. Further, the plurality of condensation tube portions 45, 45, 45 . . . in the inside of the container 10 communicate with one another via the second secondary refrigerant storing block 81-2. Further, in the cooling device 8, a secondary refrigerant storing block outer surface area increasing portion (not illustrated) that increases a contact area with the primary refrigerant in a gaseous phase by increasing a surface area of an outer surface of the secondary refrigerant storing block 81, such as a plurality of recesses and protrusions, may be formed on an outer surface of the secondary refrigerant storing block 81, in accordance with necessity.

As illustrated in FIG. 10, the secondary refrigerant 30 that flows to the inside of the container 10 from the condensation tube portion 46 in the outside of the container 10 stays for a predetermined time period after flowing to the inside of the first secondary refrigerant storing block 81-1, and thereafter branches and flows into the respective plurality of condensation tube portions 45, 45, 45 . . . in the inside of the container 10. The secondary refrigerant 30 that branches and flows into the respective plurality of condensation tube portions 45, 45, 45 . . . in the inside of the container 10 flows to the other ends from the one ends of the plurality of condensation tube portions 45, 45, 45 . . . in the inside of the container 10, meets in the inside of the second secondary refrigerant storing block 81-2 and thereafter stays for a predetermined time period, after which, the secondary refrigerant 30 flows to the condensation tube portion 46 in the outside of the container 10 from the inside of the container 10. Positions of an inflow port of the secondary refrigerant 30 of the first secondary refrigerant storing block 81-1, and an outflow port of the secondary refrigerant 30 of the second secondary refrigerant storing block 81-2 are not specially limited, but, for example, from a viewpoint of the cooling characteristics, it is preferable to dispose the inflow port and the outflow port so that a high flow velocity of the secondary refrigerant 30 is obtained in a part overlapping the heating element 100 in plan view. In FIG. 10, the position of the inflow port of the secondary refrigerant 30 of the first secondary refrigerant storing block 81-1 is provided at one end of the first secondary refrigerant storing block 81-1, and the position of the outflow port of the secondary refrigerant 30 of the second secondary refrigerant storing block 81-2 is provided at the other end of the second secondary refrigerant storing block 81-2. However, when the heating element 100 is located in a center of the bottom surface 16 of the container 10, the position of the inflow port of the secondary refrigerant 30 of the first secondary refrigerant storing block 81-1 may be provided in a center portion of the first secondary refrigerant storing block 81-1, and the position of the outflow port of the secondary refrigerant 30 of the second secondary refrigerant storing block 81-2 may be provided in a center portion of the second secondary refrigerant storing block 81-2.

Further, the secondary refrigerant storing block 81 is thermally connected to the container 10. In the cooling device 8, the first secondary refrigerant storing block 81-1 and the second secondary refrigerant storing block 81-2 are respectively in contact with the inner surface 15 of the container 10, whereby the secondary refrigerant storing block 81 is thermally connected to the container 10. Specifically, in the cooling device 8, the first secondary refrigerant storing block 81-1 and the second secondary refrigerant storing block 81-2 are in contact with side surfaces 14 of the container 10.

As illustrated in FIG. 9, in the cooling device 8 in which the secondary refrigerant storing block 81 is provided, heat H of the heating element 100 which is thermally connected to a bottom surface 16 of the container 10 is transferred to the bottom surface 16 of the container 10 from the heating element 100, and a part of the heat H of the heating element 100 that is transferred to the bottom surface 16 of the container 10 is transferred to the side surface 14 from the bottom surface 16 of the container 10. The heat H that is transferred to the side surface 14 from the bottom surface 16 of the container 10 is transferred to the secondary refrigerant 30 in the secondary refrigerant storing block 81 from the side surface 14 of the container 10, and the secondary refrigerant 30 receiving heat flows to the condensation tube portion 46 in the outside of the container 10 from the secondary refrigerant storing block 81, whereby the heat H of the heating element 100 is transported to the outside of the cooling device 8. Further, in the cooling device 8, a part of the heat H of the heating element 100 is transferred to the side surface 14 from the bottom surface 16 of the container 10, and therefore, the side surface 14 of the container 10 functions as a heat radiating portion. In other words, in the cooling device 8, on the outer surface 12 of the container 10, the outer surface to which the heating element 100 is not thermally connected can also function as the heat radiating portion.

From the above description, in the cooling device 8, the secondary refrigerant storing block 81 has a function of transferring the heat H of the heating element 100 to the secondary refrigerant 30, and therefore, cooling characteristics are further improved. Further, in the cooling device 8, the side surface 14 of the container 10 functions as the heat radiating portion, and therefore the cooling characteristics are further improved. Note that for convenience of explanation, in the cooling device 8, the parts except for the condensation tube 40 are described as having same configurations as in the cooling device according to the third embodiment, but may have same configurations as in the cooling devices according to the first, the second, and the fourth to the sixth embodiments.

Next, a cooling device according to a ninth embodiment of the present disclosure will be described. Same components as the components of the cooling devices according to the first to the eighth embodiments be described by using the same reference signs. As illustrated in FIG. 11, in a cooling device 9 according to the ninth embodiment, heat radiation fins 90 are further provided on the outer surface 12 of the container 10 of the cooling device 8 according to the eighth embodiment of the present disclosure.

In the cooling device 9, the heat radiation fins 90 are provided on an outer surface 12 to which a heating element 100 is not thermally connected, in a container 10. In other words, the heat radiation fins 90 are thermally connected to the outer surface 12 to which the heating element 100 is not thermally connected. In the cooling device 9, a plurality of heat radiation fins 90, 90, 90 . . . are provided on side surfaces 14 of the container 10, which function as heat radiating portions. A shape of the heat radiation fin 90 is a flat plate shape, a pin shape or the like and is not specially limited, but in the cooling device 9, the heat radiation fins 90 in flat plate shapes are disposed in parallel.

Note that in the cooling device 9, the heat radiation fins 90 are provided not only on the side surfaces VI of the container 10, but also on a top surface of the container 10.

In the cooling device 9, the heat radiation fins 90 are further provided on the outer surface 12 to which the heating element 100 is not thermally connected, of the container 10, so that a function as a heat radiating portion, of the outer surface 12 to which the heating element 100 is not thermally connected is further improved, and as a result, cooling characteristics of the cooling device 9 are further improved.

Note that in each of the cooling devices of the third and the sixth embodiments, the shape of the plate-shaped fin of the container inner surface area increasing portion is a square or a rectangle, but in place of this, the plate-shaped fin may be in a shape in which a base portion connecting to an inner surface of the container is wider than a tip end portion. As a shape of the plate-shaped fin in which the base portion is wider than the tip end portion, for example, a trapezoid, a triangle and the like are cited. While in the container inner surface area increasing portion, a temperature of a part in an inner portion thereof is more likely to rise due to heat transferred from the heating element, a refrigerant with a low temperature in which the container inner surface area increasing portion is immersed smoothly enters the inside of the container inner surface area increasing portion, because the plate-shaped fin is in the shape in which the base portion is wider than the tip end portion. Accordingly, heat transfer to the refrigerant in which the container inner surface area increasing portion is immersed from the heating element is made smoother, and cooling characteristics of the cooling device are further improved.

Further, in accordance with necessity, with respect to each of the above described embodiments, in order to promote change in phase of the primary refrigerant to a gaseous phase from a liquid phase, a sintered body of a thermal conductive material or an aggregate of a particulate thermal conductive material may be formed in layers on a region of a part or a whole of a surface having the heating element thermally connected thereto, and immersed in the primary refrigerant, of the inner surface of the container.

Since the cooling device of the present disclosure can exhibit excellent cooling characteristics while avoiding increase in size of the device, the cooling device of the present disclosure is usable in an extensive field, and is highly useful in a field of cooling electronic components having a large amount of heat generation mounted on circuit boards, such as a central processing unit (CPU), for example.

What is claimed is:

1. A cooling device comprising a container to which at least one heating element is thermally connected, a primary refrigerant sealed in an inside of the container, and a condensation tube through which a secondary refrigerant flows, and which penetrates through a gaseous phase portion in the inside of the container, wherein
a container inner surface area increasing portion is formed on an inner surface of the container to which the heating element is thermally connected, and
a condensation tube outer surface area increasing portion is formed on an outer surface of the condensation tube.

2. The cooling device according to claim 1, wherein the heating element is thermally connected to a part where the primary refrigerant in a liquid phase exists or a vicinity of the part where the primary refrigerant in a liquid phase exists, on an outer surface of the container.

3. The cooling device according to claim 1, wherein the container inner surface area increasing portion is immersed in the primary refrigerant in a liquid phase.

4. The cooling device according to claim 1, wherein the container inner surface area increasing portion is a plate-shaped fin, a pin fin and/or a dent.

5. The cooling device according to claim 1, wherein the container inner surface area increasing portion includes a thermal conductive member.

6. The cooling device according to claim 5, wherein the thermal conductive member is a metal member or a carbon member.

7. The cooling device according to claim 1, wherein at least a part of the container inner surface area increasing portion is a sintered body of a thermal conductive material or an aggregate of a particulate thermal conductive material.

8. The cooling device according to claim 7, wherein the sintered body of the thermal conductive material is a metal sintered body, and the metal sintered body is a sintered body of at least one kind of metal material selected from a group comprising metal powder, metal fiber, metal mesh, metal braid and metal foil.

9. The cooling device according to claim 7, wherein the aggregate of the particulate thermal conductive material is an aggregate of carbon particles.

10. The cooling device according to claim 1, wherein a condensation tube inner surface area increasing portion is formed on an inner surface of the condensation tube.

11. The cooling device according to claim 1, wherein a plurality of the condensation tubes are disposed in parallel.

12. The cooling device according to claim 1, wherein a plurality of the condensation tubes are disposed in layers.

13. The cooling device according to claim 1, wherein the condensation tube is located above the container inner surface in a part to which a heating element is thermally connected, in a direction of gravity.

14. The cooling device according to claim 1, wherein the condensation tube includes a part overlapping the heating element in plan view.

15. The cooling device according to claim 1, wherein in the condensation tube, the secondary refrigerant having a lower temperature than an allowable maximum temperature of the heating element flows.

16. The cooling device according to claim 1, wherein a shape in an orthogonal direction to a longitudinal direction in at least a partial region, of the condensation tube in the inside of the container, differs from a shape in an orthogonal direction to a longitudinal direction, of the condensation tube in an outside of the container.

17. The cooling device according to claim 1, wherein a secondary refrigerant storing block in which the secondary refrigerant is stored is further provided in the condensation tube, and the secondary refrigerant storing block is thermally connected to the container.

18. The cooling device according to claim 1, wherein a heat radiation fin is further provided on an outer surface of the container.

19. A cooling system in which a cooling device comprising a container to which at least one heating element is thermally connected, a primary refrigerant sealed in an inside of the container, and a condensation tube through which a secondary refrigerant flows, and which penetrates through a gaseous phase portion in the inside of the container, in which a container inner surface area increasing portion is formed on an inner surface of the container to which the heating element is thermally connected, and a condensation tube outer surface area increasing portion is formed on an outer surface of the condensation tube, and a secondary refrigerant cooling portion to which the condensation tube extending from the cooling device is connected are used, and the condensation tube circulates in the cooling device and the secondary refrigerant cooling portion, wherein
in the inside of the container thermally connected to the heating element, the primary refrigerant receiving heat from the heating element changes in phase to a gaseous phase from a liquid phase, the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, and the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

20. A cooling device, comprising
a first container, a primary refrigerant sealed in an inside of the first container, a condensation tube through which a secondary refrigerant flows, and which penetrates through a gaseous phase portion in the inside of the first container, and a heat transport member provided connectively to the first container, wherein
the heat transport member includes a second container to which at least one heating element is thermally connected, an extended portion including an inner space communicating with an inside of the second container, and a tertiary refrigerant sealed in an inside of the heat transport member, and the extended portion contacts the primary refrigerant in a liquid phase, and
a second container inner surface area increasing portion is formed on an inner surface of the second container to which the heating element is thermally connected, and a condensation tube outer surface area increasing portion is formed on an outer surface of the condensation tube.

21. A cooling device, comprising
a first container, a primary refrigerant sealed in an inside of the first container, a condensation tube through which a secondary refrigerant flows, and which penetrates through a gaseous phase portion in the inside of the first container, and a heat transport member provided connectively to the first container, wherein
the heat transport member includes a second container to which at least one heating element is thermally connected, and a tertiary refrigerant sealed in an inside of the second container, and the second container contacts the primary refrigerant in a liquid phase, and
a second container inner surface area increasing portion is formed on an inner surface of the second container to which the heating element is thermally connected, and a condensation tube outer surface area increasing portion is formed on an outer surface of the condensation tube.

22. A cooling device, comprising
a first container, a primary refrigerant sealed in an inside of the first container, a condensation tube through which a secondary refrigerant flows, and which penetrates through a gaseous phase portion in the inside of the first container, and a heat transport member provided connectively to the first container, wherein
the heat transport member includes a base block to which at least one heating element is thermally connected, a heat pipe portion provided to be upright on the base block, and a tertiary refrigerant sealed in an inside of the heat pipe portion, and the heat pipe portion contacts the primary refrigerant in a liquid phase.

23. A cooling device, comprising
a first container, a primary refrigerant sealed in an inside of the first container, a condensation tube through which a secondary refrigerant flows, and which penetrates through a gaseous phase portion in the inside of the first container, and a heat transport member provided connectively to the first container, wherein
the heat transport member includes a base block to which at least one heating element is thermally connected, a heat pipe provided to be buried in the base block, and a tertiary refrigerant sealed in an inside of the heat pipe.

24. The cooling device according to claim 20, wherein the second container contacts the primary refrigerant in a liquid phase.

25. The cooling device according to claim 22, wherein the base block contacts the primary refrigerant in a liquid phase.

26. The cooling device according to claim 23, wherein the base block contacts the primary refrigerant in a liquid phase.

27. The cooling device according to claim 20, wherein the heating element is thermally connected to a part where the tertiary refrigerant in a liquid phase exists or a vicinity of the part where the tertiary refrigerant in a liquid phase exists, on an outer surface of the second container.

28. The cooling device according to claim 21, wherein the heating element is thermally connected to a part where the tertiary refrigerant in a liquid phase exists or a vicinity of the part where the tertiary refrigerant in a liquid phase exists, on an outer surface of the second container.

29. The cooling device according to claim 20, wherein a heat transport member outer surface area increasing portion is formed on an outer surface of the second container and/or the extended portion.

30. The cooling device according to claim 21, wherein a heat transport member outer surface area increasing portion is formed on an outer surface of the second container.

31. The cooling device according to claim 22, wherein a heat transport member outer surface area increasing portion is formed on an outer surface of the heat pipe portion.

32. The cooling device according to claim 29, wherein the heat transport member outer surface area increasing portion has recessed and protruded portions.

33. The cooling device according to claim 30, wherein the heat transport member outer surface area increasing portion has recessed and protruded portions.

34. The cooling device according to claim 31, wherein the heat transport member outer surface area increasing portion has recessed and protruded portions.

35. The cooling device according to claim 32, wherein the recessed and protruded portions have a sintered body of a metal wire and/or a sintered body of metal powder.

36. The cooling device according to claim 32, wherein the recessed and protruded portions have recessed and protruded portions formed by etching and/or polishing.

37. The cooling device according to claim 20, wherein a shape in an orthogonal direction to a longitudinal direction in at least a partial region, of the condensation tube in the inside of the first container differs from a shape in an orthogonal direction to a longitudinal direction, of the condensation tube in an outside of the first container.

38. The cooling device according to claim 20, wherein a secondary refrigerant storing block in which the secondary refrigerant is stored is further provided at the condensation tube, and the secondary refrigerant storing block is thermally connected to the first container.

39. The cooling device according to claim 20, wherein a heat radiation fin is further provided on the outer surface of the first container.

40. A cooling system in which a cooling device comprising a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a second container to which at least one heating element is thermally connected, an extended portion having an inner space communicating with an inside of the second container, and a tertiary refrigerant sealed in an inside of the heat transport member, the extended portion contacts the primary refrigerant in a liquid phase, a second container inner surface area increasing portion is formed on an inner surface of the second container to which the heating element is thermally connected, and a condensation tube outer surface area increasing portion is formed on an outer surface of the condensation tube, and a secondary refrigerant cooling portion to which the condensation tube extending from the cooling device is connected are used, and the condensation tube circulates in the cooling device and the secondary refrigerant cooling portion, wherein
in the inside of the second container thermally connected to the heating element, the tertiary refrigerant receiving heat from the heating element changes in phase to a gaseous phase from a liquid phase, and the tertiary refrigerant in the gaseous phase flows in an inner direction of the extended portion from the inside of the second container and changes in phase to a liquid phase from the gaseous phase by a heat exchange action with the primary refrigerant, whereby heat is transferred to the primary refrigerant from the tertiary refrigerant, the primary refrigerant to which the heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

41. A cooling system in which a cooling device comprising a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a second container to which at least one heating element is thermally connected, and a tertiary refrigerant sealed in an inside of the second container, the second container contacts the primary refrigerant in a liquid phase, a second container inner surface area increasing portion is formed on an inner surface of the second container to which the heating element is thermally connected, and a condensation tube outer surface area increasing portion is formed on an outer surface of the condensation tube, and a secondary refrigerant cooling portion to which the condensation tube extending from the cooling device is connected are used, and the condensation tube circulates in the cooling device and the secondary refrigerant cooling portion, wherein
in the inside of the second container thermally connected to the heating element, the tertiary refrigerant receiving heat from the heating element changes in phase to a gaseous phase from a liquid phase, and the tertiary refrigerant in the gaseous phase changes in phase to a liquid phase from the gaseous phase by a heat exchange action with the primary refrigerant via a wall surface of the second container, whereby heat is transferred to the primary refrigerant from the tertiary refrigerant, the primary refrigerant to which the heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

42. A cooling system in which a cooling device comprising a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a base block to which at least one heating element is thermally connected, a heat pipe portion provided to be upright on the base block, and a tertiary refrigerant sealed in an inside of the heat pipe portion, and the heat pipe portion contacts the primary refrigerant in a liquid phase, and a secondary refrigerant cooling portion to which the condensation tube extending from the cooling device is connected are used, and the condensation tube circulates in the cooling device and the secondary refrigerant cooling portion, wherein
heat is transferred to the heat pipe portion from the base block thermally connected to the heating element, the tertiary refrigerant sealed in the heat pipe portion receiving heat from the base block changes in phase to a gaseous phase from a liquid phase, and the tertiary refrigerant in the gaseous phase flows through an inside of the heat pipe portion and changes in phase to a liquid phase from the gaseous phase by a heat exchange action with the primary refrigerant, whereby heat is transferred to the primary refrigerant from the tertiary refrigerant, the primary refrigerant to which the heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.

43. A cooling system in which a cooling device comprising a first container, a primary refrigerant sealed in an inside of the first container, a condensation tube through which a secondary refrigerant flows, and which penetrates through a gaseous phase portion in the inside of the first container, and a heat transport member provided connectively to the first container, in which the heat transport member includes a base block to which at least one heating element is thermally connected, a heat pipe provided to be buried in the base block, and a tertiary refrigerant sealed in an inside of the heat pipe, and a secondary refrigerant cooling portion to which the condensation tube extending from the cooling device is connected are used, and the condensation tube circulates in the cooling device and the secondary refrigerant cooling portion, wherein
heat is transferred to the heat pipe from the base block thermally connected to the heating element, the tertiary refrigerant sealed in the heat pipe receiving heat from the base block changes in phase to a gaseous phase from a liquid phase, the tertiary refrigerant in the gaseous phase flows through an inside of the heat pipe, heat is transferred to the primary refrigerant from the tertiary refrigerant, the primary refrigerant to which the heat is transferred from the tertiary refrigerant changes in phase to a gaseous phase from the liquid phase in the inside of the first container, and the primary refrigerant in the gaseous phase changes in phase to a liquid phase from the gaseous phase by a heat exchange action of the condensation tube, whereby heat is transferred to the secondary refrigerant flowing through the condensation tube from the primary refrigerant, the secondary refrigerant to which the heat is transferred flows through the condensation tube to the secondary refrigerant cooling portion to be cooled to a predetermined temperature, and the secondary refrigerant cooled in the secondary refrigerant cooling portion flows through the condensation tube to return to the cooling device.
